(19) United States
(12) Patent Application Publication
(10) Pub. No.: US 2025/0246551 A1
(43) Pub. Date: Jul. 31, 2025

(54) Conductive Structures and Dielectric Structures in Interconnect Structures

(71) Applicant: Taiwan Semiconductor Manufacturing Company, Ltd., Hsinchu (TW)

(72) Inventors: Kai-Chi LO, Hsinchu (TW); Chih-Yi CHANG, New Taipei (TW); Hung-Yi HUANG, Hsinchu (TW); Wei-Yip LOH, Hsinchu (TW)

(73) Assignee: Taiwan Semiconductor Manufacturing Company, Ltd., Hsinchu (TW)

(21) Appl. No.: 18/924,839

(22) Filed: Oct. 23, 2024

Related U.S. Application Data
(60) Provisional application No. 63/626,786, filed on Jan. 30, 2024.

(51) Int. Cl. H01L 23/535; H01L 21/768; H01L 29/06; H01L 29/423; H01L 29/775; H01L 29/786

(52) U.S. Cl. CPC H01L 23/535; H01L 21/76805; H01L 21/7684; H01L 21/76895; H10D 30/43; H10D 30/6735; H10D 30/6757; H10D 62/121

(57) ABSTRACT

An interconnect structure and a method of fabricating the interconnect structure are disclosed. The interconnect structure includes an inter-metal dielectric (IMD) structure disposed on a transistor, first and second conductive lines disposed in the IMD structure, and a third conductive line, disposed in the IMD structure. The first conductive line includes a top surface with a first width and a bottom surface with a second width greater than the first width. The third conductive line includes an upper surface with a third width and a lower surface with a fourth width smaller than the third width. Metals of the first and third conductive lines are different from each other.

### CROSS-REFERENCE TO RELATED APPLICATIONS

This application claims the benefit of U.S. Provisional Patent Application No. 63/626,786, titled “Composite Interconnect by Damascene Process,” filed Jan. 30, 2024, which is incorporated by reference herein in its entirety.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs, fin field effect transistors (finFETs), and gate-all-around field effect transistors (GAA FETs) and interconnect structures disposed on the semiconductor devices. Such scaling down has increased the complexity of semiconductor manufacturing processes along with increased resistivity, increased resistance-capacitance (RC) delay, and decreased breakdown voltage of the interconnect structures.

### BRIEF DESCRIPTION OF THE DRAWINGS

Aspects of this disclosure are best understood from the following detailed description when read with the accompanying figures.

FIG. 1 illustrates an isometric view of a semiconductor device, in accordance with some embodiments.

FIG. 2 illustrates a cross-sectional view of a semiconductor device, in accordance with some embodiments.

FIGS. 3A-3B, 4A-4B, 5A-5B, and 6A-6E illustrate different cross-sectional views of different interconnect structures on a semiconductor device, in accordance with some embodiments.

FIG. 7 is a flow diagram of a method for fabricating an interconnect structure on a semiconductor device, in accordance with some embodiments.

FIGS. 8-12 illustrate cross-sectional views of an interconnect structure on a semiconductor device at various stages of its fabrication process, in accordance with some embodiments.

FIG. 13 is a flow diagram of a method for fabricating another interconnect structure on a semiconductor device, in accordance with some embodiments.

FIGS. 14-17 illustrate cross-sectional views of another interconnect structure on a semiconductor device at various stages of its fabrication process, in accordance with some embodiments.

FIG. 18 is a flow diagram of a method for fabricating another interconnect structure on a semiconductor device, in accordance with some embodiments.

FIGS. 19-23 illustrate cross-sectional views of another interconnect structure on a semiconductor device at various stages of its fabrication process, in accordance with some embodiments.

FIG. 24 is a flow diagram of a method for fabricating another interconnect structure on a semiconductor device, in accordance with some embodiments.

FIGS. 25-28 illustrate cross-sectional views of another interconnect structure on a semiconductor device at various stages of its fabrication process, in accordance with some embodiments.

FIG. 29 is a flow diagram of a method for fabricating another interconnect structure on a semiconductor device, in accordance with some embodiments.

FIGS. 30-34 illustrate cross-sectional views of another interconnect structure on a semiconductor device at various stages of its fabrication process, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Spatially relative terms, such as “beneath,” “below,” “lower,” “above,” “upper,” and the like may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5-20% of the value (e.g., ±1%, ±2%, ±3%, ±4%, ±5%, ±10%, ±10-15%, ±15˜20% of the value). These values are merely examples and are not intended to be limiting. The terms “about” and “substantially” can refer to a percentage of the values as interpreted by those skilled in relevant art(s) in light of the teachings herein.

GAA transistor structures may be patterned by any suitable method. For example, the structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA transistor structure.

The increasing demand for small, portable multifunctional electronic devices has increased the demand for low power devices that can perform increasingly complex and sophisticated functions while providing ever-increasing storage capacity. As a result, there is a continuing trend in the semiconductor industry to manufacture low-cost, high-performance, and low-power integrated circuits (ICs) with semiconductor devices and interconnect structures. These goals have been achieved in large part by scaling down the dimensions of the semiconductor devices and/or interconnect structures. However, continued scaling of interconnect lines of interconnect structures introduces considerable challenges, such as increased resistance and capacitance in interconnect structures. The increased resistance can arise from increased electron scattering in narrow copper (Cu) interconnect lines that are scaled down to cross-sectional areas below about 400 nm². The increased capacitance can arise from structural damage to inter-metal dielectric (IMD) structures surrounding the narrow Cu interconnect lines. The structural damage to the IMD structures can occur from exposure to high energy ions used in the formation of narrow Cu interconnect lines in trenches with widths below about 20 nm.

To address the abovementioned challenges, the present disclosure provides example interconnect structures with reduced resistance and capacitance and example methods of forming the example interconnect structures. In some embodiments, an interconnect structure can include interconnect lines with different cross-sectional areas having different metals to reduce the overall resistance of the interconnect structure. The different metals can have electron mean free path and bulk resistivity different from each other. As electron scattering in metals depends on the electron mean free path length and increase with reduced dimension of metals, thus increasing resistance in metals, the interconnect lines with cross-sectional areas less than about 400 nm² can have metals with electron mean free path lengths shorter than that of metals of the interconnect lines with cross-sectional areas greater than about 400 nm² to reduce resistance in the interconnect structure. Also, the interconnect lines with cross-sectional areas greater than about 400 nm² can have metals with bulk resistivity greater than that of metals of the interconnect lines with cross-sectional areas less than about 400 nm² to reduce resistance in the interconnect structure. In some embodiments, the interconnect structure can include ruthenium (Ru)-based interconnect lines with cross-sectional areas less than about 400 nm² and Cu-based interconnect lines with cross-sectional areas greater than about 400 nm², as Ru has an electron mean free path length shorter than that of Cu and Cu has a bulk resistivity greater than that of Ru.

In some embodiments, interconnect lines with different widths can be formed at different stages of the fabrication process of the interconnect structure to prevent or minimize structural damage to the IMD structures, thus reducing capacitance of the interconnect structure. In some embodiments, the interconnect lines with widths below 20 nm can be formed prior to the formation of the IMD structures and the interconnect lines with widths above 20 nm can be formed after the formation of the IMD structures. The formation of the interconnect lines with widths below 20 nm prior to the formation of the IMD structures can prevent the IMD structures from being exposed to high energy ions used in the formation of interconnect lines in narrow trenches with widths below about 20 nm.

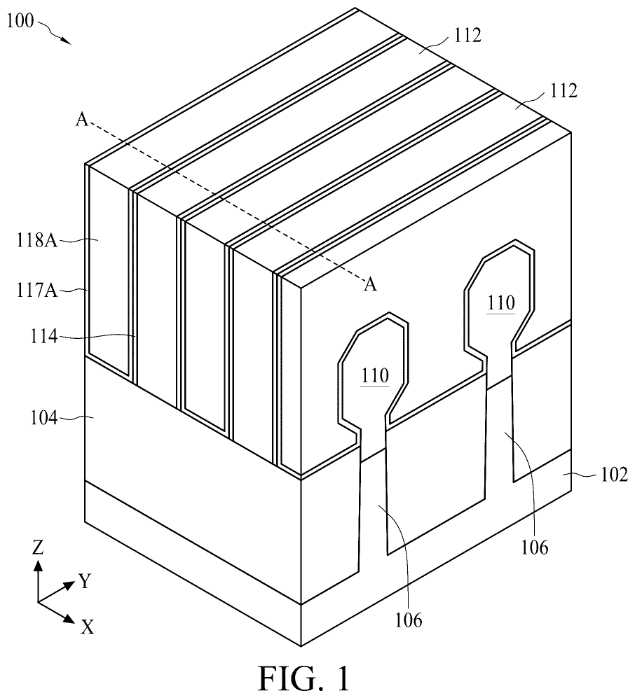

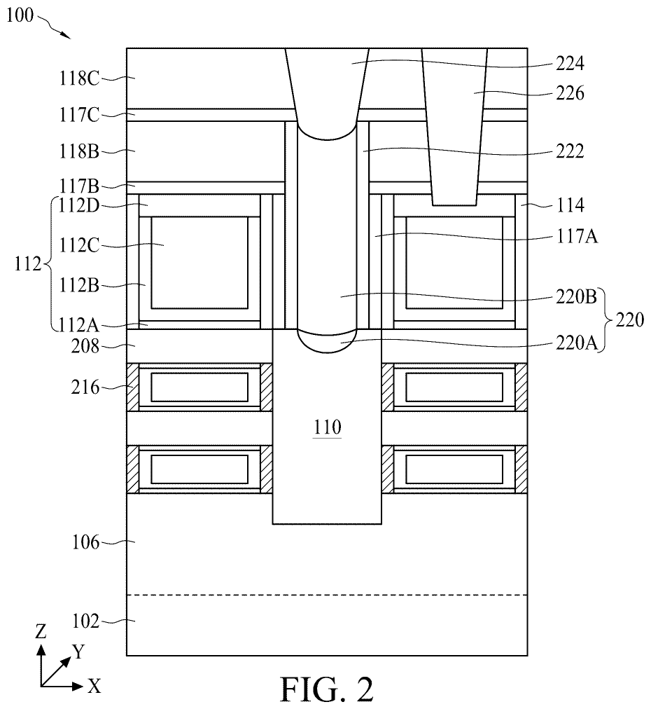

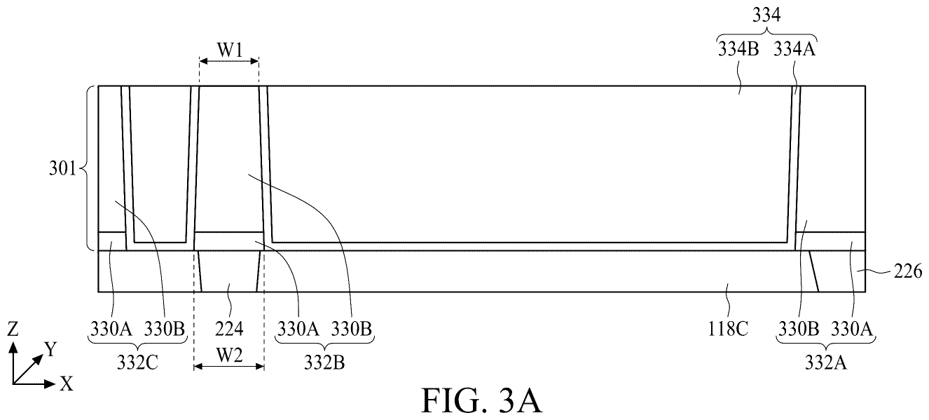

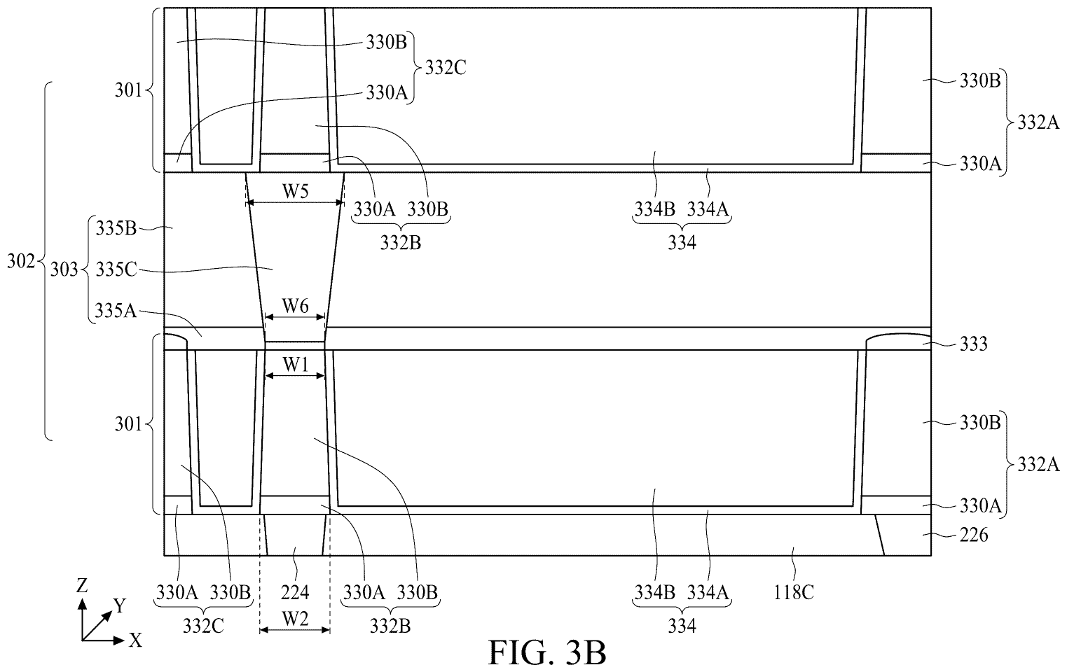

FIG. 1 illustrates an isometric view of a semiconductor device 100, which can represent a GAA FET 100, according to some embodiments. FIG. 2 illustrate a cross-sectional view of GAA FET 100, along line A-A of FIG. 1, with additional structures that are not shown in FIG. 1 for simplicity, according to some embodiments. FIGS. 3A, 4A, 5A, and 6A illustrate cross-sectional views of interconnect structures 301, 401, 501, and 601 that can be disposed on GAA FET 100, according to some embodiments. FIGS. 3B, 4B, 5B, and 6B-6E illustrate cross-sectional views of multi-level interconnect structures 302, 402, 502, and 602 that can be disposed on GAA FET 100, according to some embodiments. The discussion of elements in FIGS. 1, 2, 3A, 3B, 4A, 4B, 5A, 5B, and 6A-6E with the same annotations applies to each other, unless mentioned otherwise.

Referring to FIGS. 1 and 2, in some embodiments, GAA FET 100 can include (i) a substrate 102, (ii) shallow trench isolation (STI) regions 104 disposed on substrate 102, (iii) fin-shaped base structures 106 (also referred to as a “sheet base 106” or a “fin base 106”) disposed on substrate 102, (iv) nanostructured channel regions 208 disposed on base structure 106, (v) S/D regions 110 disposed adjacent to nanostructured channel regions 208, (vi) gate structures 112 surrounding nanostructured channel regions 208, (vii) outer gate spacers 114, (viii) inner gate spacers 216, (ix) etch stop layers (ESLs) 117A-117C, (x) interlayer dielectric (ILD) layers 118A-118C, (xi) a S/D contact structure 220 disposed on S/D regions 110, (xii) a barrier layer 222 disposed along sidewall of contact structure 220, (xiii) a via structure 224 disposed on S/D contact structure 220, and (xiv) a gate contact structure 226 disposed on gate structure 112.

In some embodiments, substrate 102 can be a semiconductor material, such as silicon (Si), germanium (Ge), silicon germanium (SiGe), a silicon-on-insulator (SOI) structure, and a combination thereof. Further, substrate 102 can be doped with p-type dopants (e.g., boron, indium, aluminum, or gallium) or n-type dopants (e.g., phosphorus or arsenic). In some embodiments, STI regions 104 can include an insulating material, such as silicon oxide (SiO₂), silicon nitride (SiN), silicon oxynitride (SiON), silicon oxycarbide (SiOC), silicon carbon nitride (SiCN), silicon oxycarbon nitride (SiOCN), and silicon germanium oxide (SiGeOₓ). In some embodiments, base structures 106 can include a material similar to substrate 102. Base structures 106 can have elongated sides extending along an X-axis.

In some embodiments, nanostructured channel regions 208 can be in the form of nanosheets, nanowires, nanorods, nanotubes, or other suitable nanostructured shapes. As used herein, the term “nanostructured” defines a structure, layer, and/or region as having a horizontal dimension (e.g., along an X- and/or Y-axis) and/or a vertical dimension (e.g., along a Z-axis) less than about 100 nm, for example about 90 nm, about 50 nm, about 10 nm, or other values less than about 100 nm. Nanostructured channel regions 208 can include semiconductor materials similar to or different from substrate 102. In some embodiments, nanostructured channel regions 208 can include Si, silicon arsenide (SiAs), silicon phosphide (SiP), silicon carbide (SiC), silicon carbon phosphide (SiCP), silicon germanium (SiGe), silicon germanium boron (SiGeB), germanium boron (GeB), silicon germanium stannum boron (SiGeSnB), a III-V semiconductor compound, or other suitable semiconductor materials. In some embodiments, each of nanostructured channel regions 208 can have a thickness of about 3 nm to about 15 nm along a Z-axis. Though two nanostructured channel regions 208 are shown under gate structure 112, GAA FET 100 can have any number of nanostructured channel regions 208. Though rectangular cross-sections of nanostructured channel regions 208 are shown, nanostructured channel regions 208 can have cross-sections of other geometric shapes (e.g., circular, elliptical, triangular, or polygonal).

In some embodiments, S/D regions 110 can include an epitaxially-grown semiconductor material, such as Si, and n-type dopants, such as phosphorus and other suitable n-type dopants for n-type GAA FET 100. S/D regions 110 can include an epitaxially-grown semiconductor material, such as Si and SiGe, and p-type dopants, such as boron and other suitable p-type dopants for p-type GAA FET 100. Each of S/D regions 110 may refer to a source or a drain, individually or collectively dependent upon the context.

Each gate structure 112 can be multi-layered structures and can include (i) an interfacial oxide (IL) layer 112A, (ii) a high-k (HK) gate dielectric layer 112B, (iii) a conductive layer 112C, and (iv) a gate capping layer 112D. In some embodiments, IL layer 112A can be disposed directly on topmost nanostructured channel regions 208. In some embodiments, IL layer 112A can include SiO₂, SiGeOₓ, or germanium oxide (GeOₓ). In some embodiments, HK gate dielectric layer 112B can be disposed directly on IL layer 112A and can include a high-k dielectric material, such as hafnium oxide (HfO₂), titanium oxide (TiO₂), hafnium zirconium oxide (HfZrO), tantalum oxide (Ta₂O₃), hafnium silicate (HfSiO₄), zirconium oxide (ZrO₂), and zirconium silicate (ZrSiO₂). In some embodiments, the sidewalls of HK gate dielectric layer 112B can be in contact with sidewalls of outer gate spacers 114.

In some embodiments, conductive layer 112C can be disposed on HK gate dielectric layer 112B and can be multi-layered structures. The different layers of conductive layer 112C are not shown for simplicity. In some embodiments, conductive layer 112C can include a work function metal (WFM) layer disposed on HK gate dielectric layer 112B and a gate metal fill layer disposed on the WFM layer. In some embodiments, the WFM layer can include substantially Al-free (e.g., with no Al) Ti-based or Ta-based nitrides or alloys, such as titanium nitride (TiN), titanium silicon nitride (TiSiN), titanium gold (Ti—Au) alloy, titanium copper (Ti—Cu) alloy, tantalum nitride (TaN), tantalum silicon nitride (TaSiN), tantalum gold (Ta—Au) alloy, and tantalum copper (Ta—Cu). In some embodiments, the WFM layer can include titanium aluminum (TiAl), titanium aluminum carbide (TiAlC), tantalum aluminum (TaAl), tantalum aluminum carbide (TaAlC), Al-doped Ti, Al-doped TiN, Al-doped Ta, Al-doped TaN, or other suitable Al-based materials. In some embodiments, the gate metal fill layer can include a suitable conductive material, such as tungsten (W), titanium (Ti), silver (Ag), ruthenium (Ru), molybdenum (Mo), copper (Cu), cobalt (Co), Al, iridium (Ir), nickel (Ni), metal alloys, and a combination thereof.

In some embodiments, gate capping layer 112D can be disposed directly on HK gate dielectric layer 112B and conductive layer 112C. Gate capping layer 112D can provide a conductive interface between conductive layer 112C and gate contact structure 226 to electrically connect conductive layer 112C to gate contact structure 226 without forming gate contact structure 226 directly on or in conductive layer 112C. Gate contact structure 226 is not formed directly on or in conductive layer 112C to prevent contamination by any of the processing materials used in the formation of gate contact structure 226. Contamination of conductive layer 112C can lead to the degradation of device performance. Thus, with the use of gate capping layer 112D, gate structure 112 can be electrically connected to gate contact structure 226 without compromising the integrity of gate structure 112. In some embodiments, gate capping layer 112D can include a metallic material, such as W, Ru, Mo, Co, other suitable metallic materials, and a combination thereof.

In some embodiments, gate structures 112 can be electrically isolated from adjacent S/D regions 110 and from S/D contact structure 220 by outer gate spacers 114 and inner gate spacers 216. In some embodiments, outer gate spacers 114 and inner gate spacers 216 can include insulating materials, such as SiO₂, SiN, SiON, SiCN, SiOCN, and other suitable insulating materials. In some embodiments, (i) ESL 117A can be disposed directly on S/D regions 110, (ii) ILD layer 118A can be disposed directly on ESL 117A, (iii) ESL 117B can be disposed directly on ILD layer 118A, gate structures 112, and outer gate spacers 114, (iv) ILD layer 118B can be disposed directly on ESL 117B and surrounding S/D contact structure 220 and gate contact structure 226, (v) ESL 117C can be disposed directly on ILD layer 118B and surrounding via structure 224 and gate contact structure 226, and (vi) ILD layer 118C can be disposed directly on ESL 117C and surrounding via structure 224 and gate contact structure 226. In some embodiments, ESLs 117A-117C and ILD layers 118A-118C can include insulating materials, such as SiO₂, SIN, SiON, SiCN, SiOCN, and other suitable insulating materials.

In some embodiments, S/D contact structure 220 can include (i) a silicide layer 220A and (ii) a conductive fill layer 220B disposed on silicide layer 220A. In some embodiments, silicide layer 220A in n-type GAA FET 100 can include titanium silicide (TiₓSi_{y}), tantalum silicide (TaₓSi_{y}), molybdenum (MoₓSi_{y}), zirconium silicide (ZrₓSi_{y}), hafnium silicide (HfₓSi_{y}), scandium silicide (ScₓSi_{y}), yttrium silicide (YₓSi_{y}), terbium silicide (TbₓSi_{y}), lutetium silicide (LuₓSi_{y}), erbium silicide (ErₓSi_{y}), ybtterbium silicide (YbₓSi_{y}), europium silicide (EuₓSi_{y}), thorium silicide (ThₓSi_{y}), other suitable metal silicide materials, or a combination thereof. In some embodiments, silicide layer 220A in p-type GAA FET 100 can include nickel silicide (NiₓSi_{y}), cobalt silicide (CoₓSi_{y}), manganese silicide (MnₓSi_{y}), tungsten silicide (WₓSi_{y}), iron silicide (FeₓSi_{y}), rhodium silicide (RhₓSi_{y}), palladium silicide (PdₓSi_{y}), ruthenium silicide (RuₓSi_{y}), platinum silicide (PtₓSi_{y}), iridium silicide (IrₓSi_{y}), osmium silicide (OsₓSi_{y}), other suitable metal silicide materials, or a combination thereof. In some embodiments, conductive fill layer 220B can include a conductive material, such as Co, W, Ru, Al, Mo, Ir, Ni, Osmium (Os), rhodium (Rh), other suitable conductive materials, and a combination thereof.

In some embodiments, S/D contact structure 220 can be surrounded by barrier layer 222 and can be configured to prevent or minimize the diffusion of oxygen atoms from ILD layers 118A and 118B into conductive fill layer 220B. Barrier layer 222 can also be configured to prevent or minimize the diffusion of metal atoms from conductive fill layer 220B into gate structures 112. In some embodiments, barrier layer 222 can include oxygen-free dielectric nitride layers (e.g., SiN layers), oxygen-free dielectric carbide layers (e.g., silicon carbide (SiC) layers), or oxygen-free carbon nitride layers (e.g., silicon carbon nitride (SiCN) layers). In some embodiments, barrier layer 222 can have a thickness of about 2 nm to about 9 nm along an X-axis axis to adequately prevent or minimize (i) the diffusion of oxygen atoms from ILD layers 118A and 118B into conductive fill layer 220B, and (ii) the diffusion of metal atoms from conductive fill layer 220B into gate structures 112.

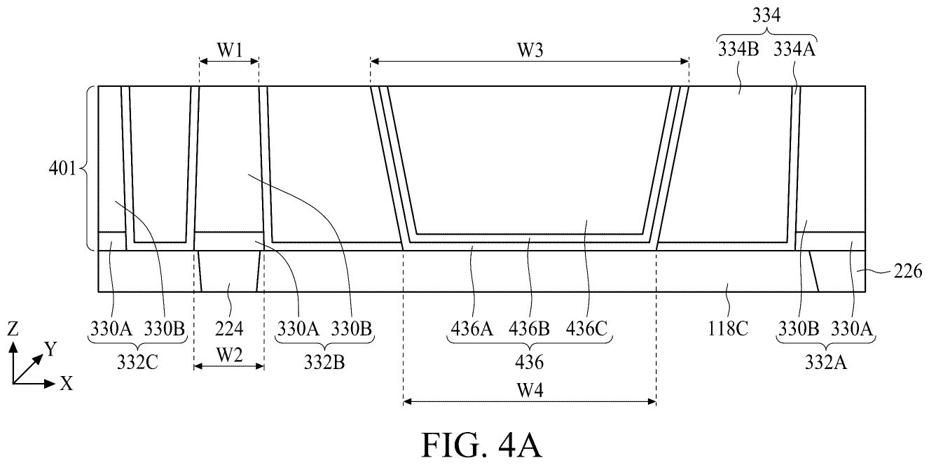

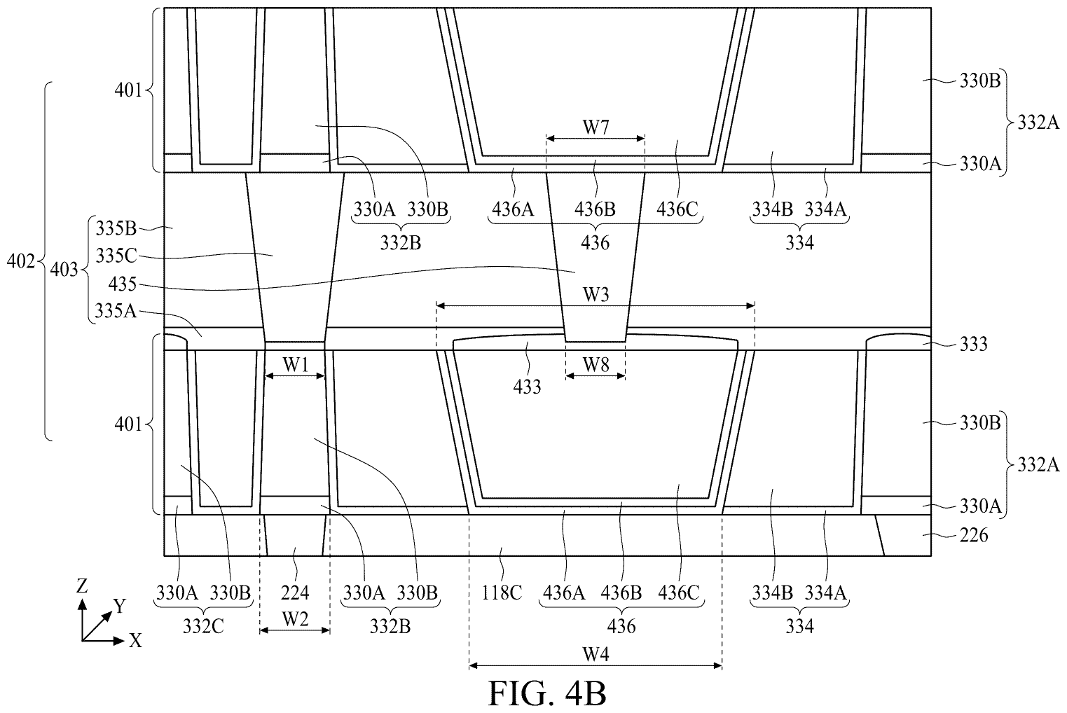

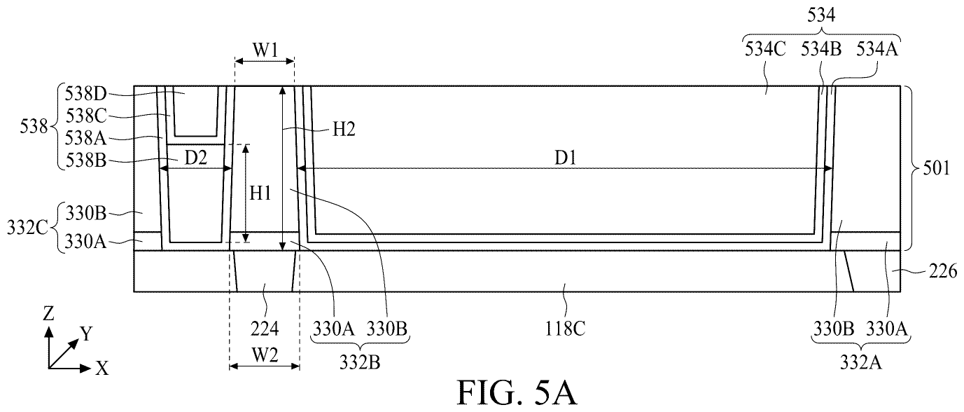

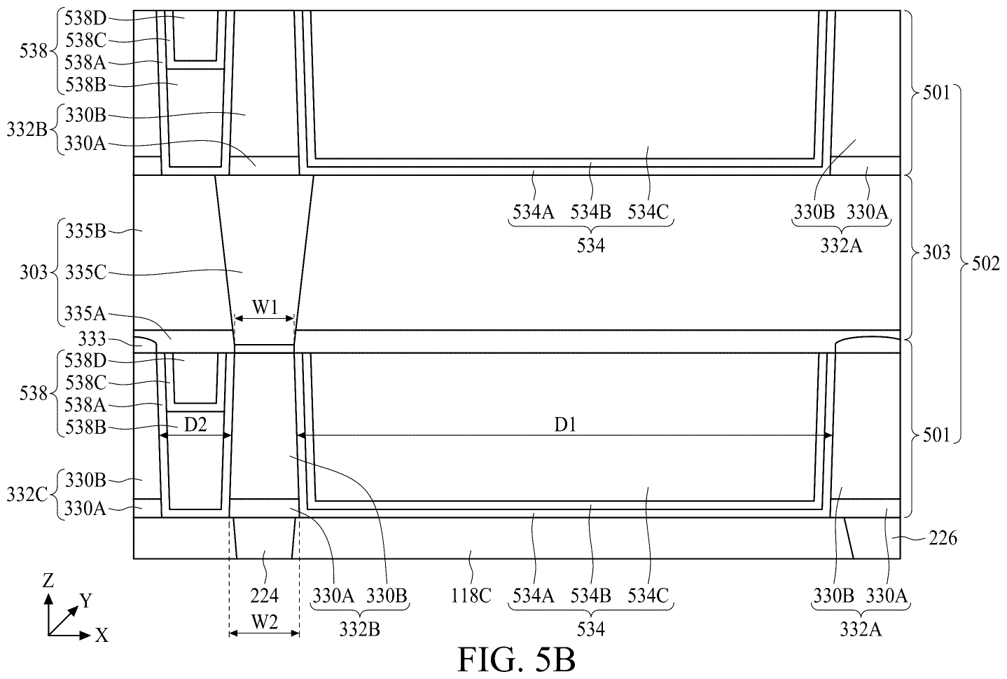

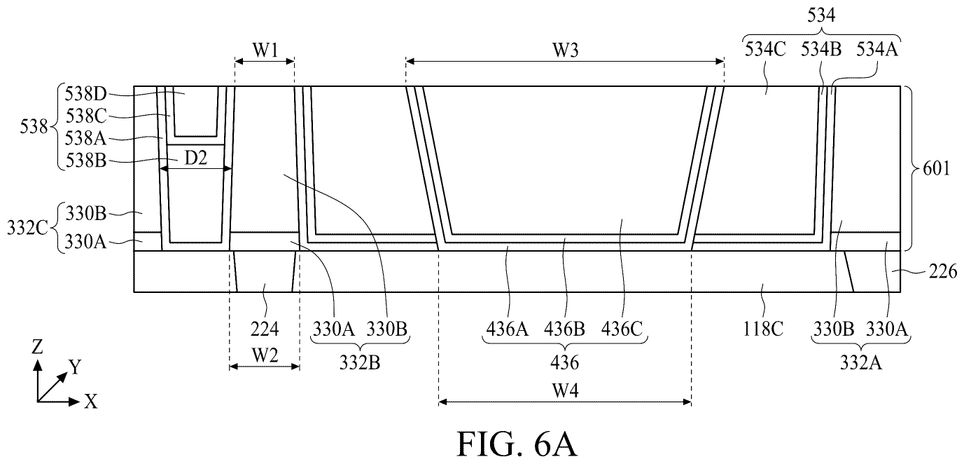

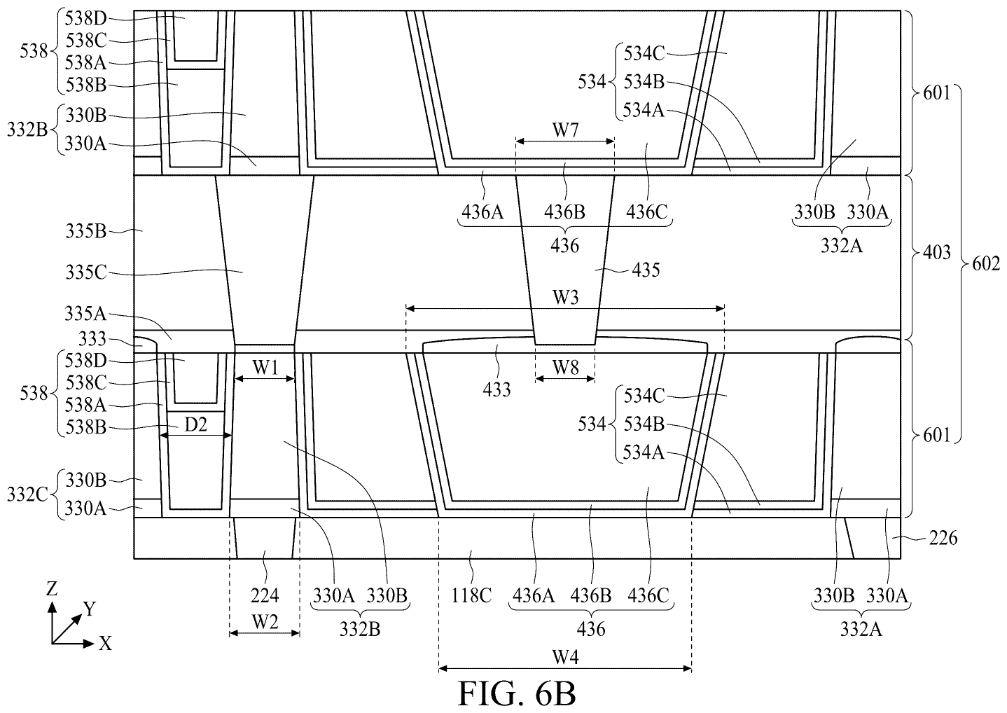

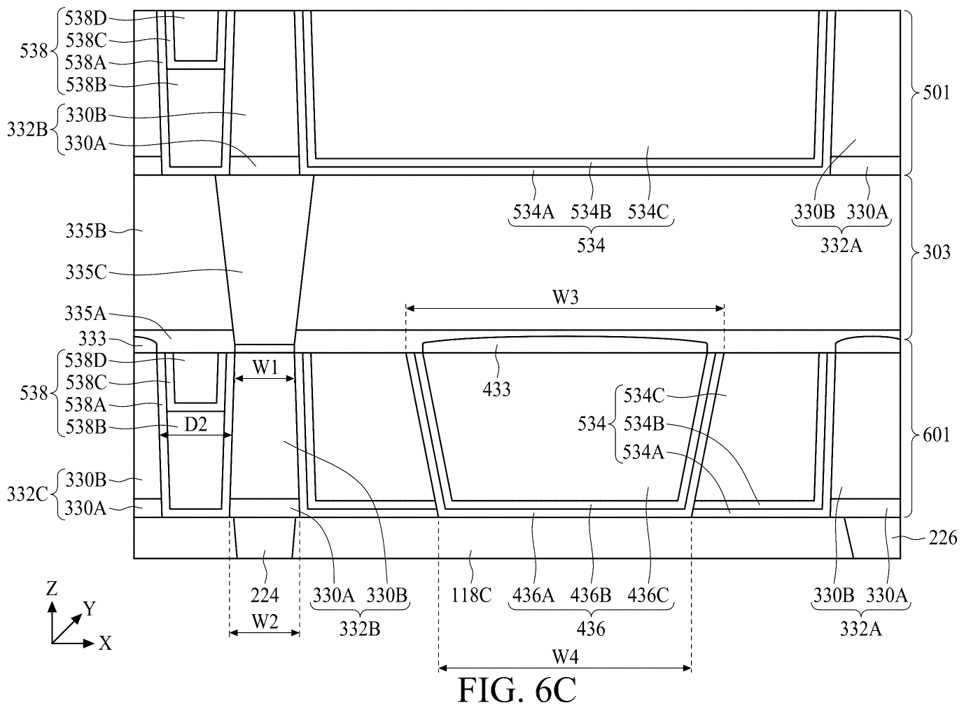

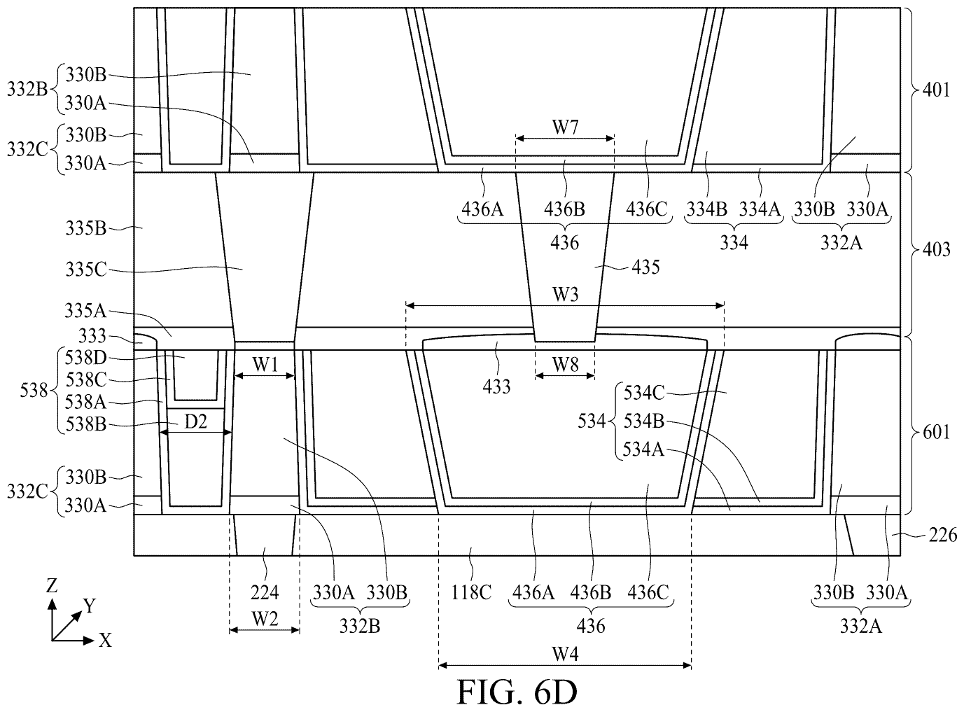

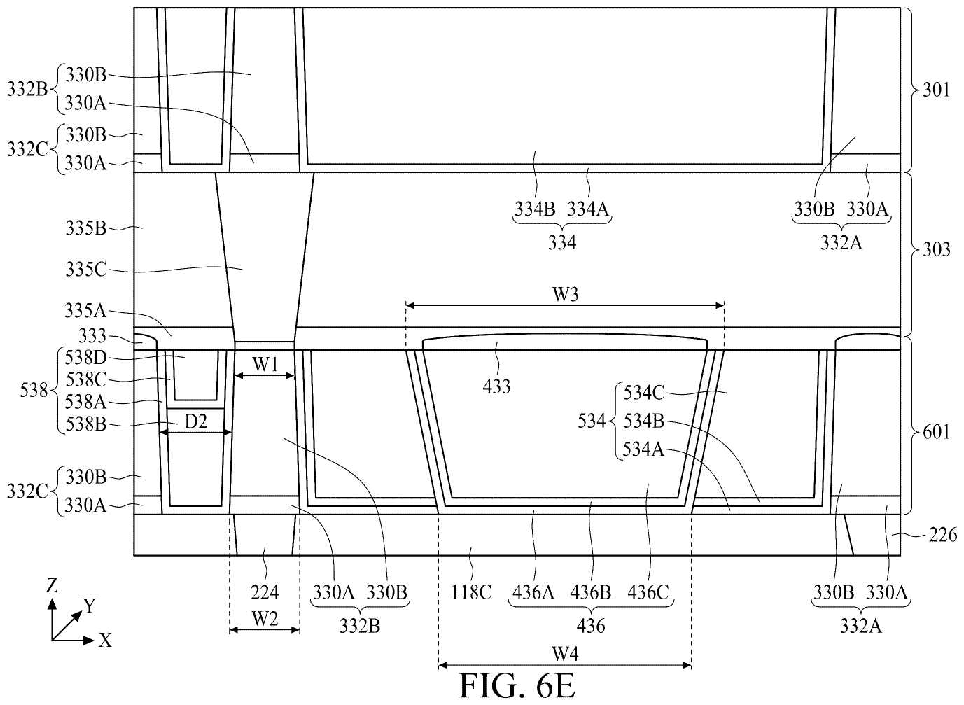

S/D contact structure 220 can electrically connect S/D region 110 to overlying interconnect structure 301 (FIG. 3A), 302 (FIG. 3B), 401 (FIG. 4A), 402 (FIG. 4B), 501 (FIG. 5A), 502 (FIG. 5B), 601 (FIG. 6A), or 602 (FIGS. 6B-6E) through via structure 224. Via structure 224 can be disposed in S/D contact structure 220 and can include conductive materials, such as Ru, W, Ni, Al, Mo, Ir, Os, and other suitable conductive materials. Gate contact 226 can electrically connect gate structure 112 to overlying interconnect structure 301, 302, 401, 402, 501,502, 601, or 602 and can include conductive materials, such as Ru, W, Ni, Al, Mo, Ir, Os, and other suitable conductive materials.

Referring to FIG. 3A, in some embodiments, interconnect structure 301 can be disposed on ILD layer 118C and can include (i) interconnect lines 332A-332C (also referred to as “conductive lines 332A-332C”) and (ii) IMD structures 334. In some embodiments, interconnect line 332A can be disposed directly on and electrically connected to gate contact structure 226. In some embodiments, interconnect line 332B can be disposed directly on and electrically connected to via structure 224. In some embodiments, interconnect line 332C can be electrically connected to other element (not shown) of GAA FET 100. Though three interconnect lines 332A-332C are shown in FIG. 3A, interconnect structure 301 can have any number of interconnect lines. The elongated sides of interconnect lines 332A-332C can be along a Y-axis and the dimensions along the elongated sides are referred to herein as “lengths.” The shorter sides of interconnect lines 332A-332C can be along an X-axis and the dimensions along the shorter sides are referred to herein as “widths.” FIG. 3A shows the cross-sectional view of interconnect lines 332A-332C along their shorter sides, that is along their widths.

In some embodiments, each of interconnect lines 332A-332C can have (i) a cross-sectional area less than about 400 nm² (e.g., about 25 nm² to about 380 nm²) along its shorter side (e.g., along an X-axis), (ii) a tapered cross-sectional profile, along an XZ-plane, with widths increasing from its top surface to its bottom surface, (iii) a width W1 of its top surface smaller than a width W2 of its bottom surface, and (iv) widths W1 and W2 less than about 20 nm. The structural profiles of interconnect lines 332A-332C can depend on the process of forming interconnect lines 332A-332C with cross-sectional areas less than about 400 nm², as described in detail below.

In some embodiments, each of interconnect lines 332A-332C can be liner-free and can include (i) a conductive metal nitride layer 330A and (ii) a metal layer 330B disposed on conductive metal nitride layer 330A. Conductive metal nitride layer 330A can serve as a glue layer for reliable contact metal layer 330B and underlying structures/layers (e.g., via structure 224, gate contact structure 226, and ILD layer 118C). In addition, conductive metal nitride layer 330A can serve as an etch stop layer during the formation of metal layer 330B. In some embodiments, conductive metal nitride layer 330A can include TiN, aluminum nitride (AlN), or other suitable conductive metal nitrides.

In some embodiments, metal layer 330B can include a Cu-free metal layer having a metal with an electron mean free path length (e.g., about 1 nm to about 30 nm) that is shorter than an electron mean free path length (e.g., about 40 nm) of Cu. In some embodiments, metal layer 330B can include Ru, Al, Cr, Mo, Ti, W, or other suitable metals. The Cu-free metal layer and/or short electron mean free path length of metal in metal layer 330B can reduce electrical resistance in interconnect lines 332A-332C with cross-sectional areas less than about 400 nm² compared to electrical resistance in Cu-based metal layer interconnect lines with similar cross-sectional areas.

In some embodiments, each of IMD structures 334 can be disposed between interconnect lines 332A-332C and electrically isolate interconnect lines 332A-332C from each other. In some embodiments, each of IMD structures 334 can include (i) a dielectric capping layer 334A and (ii) a dielectric fill layer 334B. Dielectric capping layer 334A can serve as a barrier layer for protecting interconnect lines 332A-332C from thermal damage, environmental damage, and/or damage from processing chemicals during the formation of interconnect structure 301. In some embodiments, dielectric capping layer 334A can have a thickness of about 1 nm to about 2 nm to adequately protect interconnect lines 332A-332C from the damage. In some embodiments, dielectric capping layer 334A can include an insulating material having silicon, oxygen, and/or carbon. In some embodiments, dielectric fill layer 334B can include a low dielectric constant (e.g., dielectric constant less than about 3.0) to minimize resistance-capacitance (RC) delay of interconnect structure 301. In some embodiments, dielectric fill layer 334B can include an insulating material having silicon, oxygen, carbon, and/or hydrogen. In some embodiments, top surfaces of dielectric capping layer 334A, dielectric fill layer 334B, and metal layer 330B can be substantially coplanar with respect to each other.

Referring to FIG. 3B, in some embodiments, multi-level interconnect (MLI) structure 302 can be disposed on ILD layer 118C, instead of interconnect structure 301. In some embodiments, MLI structure 302 can include a stack of interconnect structures 301 and 303. Interconnect structures 301 can be electrically connected to each other though interconnect structure 303. In some embodiments, interconnect structure 301 can include conductive capping layers 333 disposed directly on metal layers 330B of interconnect lines 332A-332C when an interconnect structure, such as interconnect structure 303 is stacked on interconnect structure 301. Conductive capping layers 333 can provide conductive interfaces between interconnect lines 332A-332C and overlying conductive structures (e.g., vias) of interconnect structure 303, as discussed below. In some embodiments, conductive capping layers 333 can include a conductive material, such a nitride (e.g., ruthenium nitride (RuN)) of the metal of metal layer 330B.

In some embodiments, interconnect structure 303 can include (i) an ESL 335A, (ii) an IMD layer 335B, and (iii) a via 335C. ESL 335A can be disposed on dielectric fill layer 334B and portions of conductive capping layers 333 that are not covered by via 335C. In some embodiments, ESL 335A can include an insulating material, such as SiO₂, SiN, SiC, SiON, SiCN, SiOCN, and other suitable insulating materials. IMD layer 335B can be disposed on ESL 335A and can surround via 335C. In some embodiments, IMD layer 335B can include an insulating material having silicon, oxygen, carbon, and/or hydrogen. In some embodiments, top surfaces of IMD layer 335B and via 335C can be substantially coplanar with respect to each other.

In some embodiments, via 335C can be disposed directly on conductive capping layer 333 that is on interconnect line 332B. Conductive capping layer 333 can provide a conductive interface between interconnect line 332B and via 335C to electrically connect interconnect line 332B to via 335C without forming via 335C directly on or within interconnect line 332B. Via 335C is not formed directly on or within interconnect line 332B to prevent contamination of interconnect line 332B by any of the processing materials used in the formation of via 335C. Via 335C can electrically connect interconnect line 332B of bottom interconnect structure 301 to interconnect line 332B of top interconnect structure 301. Top surface of via 335C can be in direct contact with bottom surface of conductive metal nitride layer 330A of interconnect line 332B. Though one via 335C is shown in FIG. 3B, interconnect structure 303 can have other vias 335C (not visible in the cross-sectional view of FIG. 3B) to electrically connect interconnect lines 332A and/or 332C of top and bottom interconnect structures 301. In some embodiments, via 335C can include a conductive material, such as such as Ru, Co, Ni, Al, Mo, W, Ir, Os, Cu, and Pt. In some embodiments, via 335C can have (i) a tapered cross-sectional profile, along an XZ-plane, with widths increasing from its bottom surface to its top surface, and (ii) width W5 of its top surface greater than width W6 of its bottom surface.

Referring to FIG. 4A, in some embodiments, interconnect structure 401 can be disposed on ILD layer 118C, instead of interconnect structure 301. The discussion of interconnect structure 301 applies to interconnect structure 401, unless mentioned otherwise. In some embodiments, interconnect structure 401 can include (i) interconnect lines 332A-332C, (ii) interconnect line 436, and (ii) IMD structures 334. In some embodiments, interconnect line 436 can be disposed directly on ILD layer 118C and can be electrically connected to other element (not shown) of GAA FET 100. In some embodiments, IMD structure 334 can surround interconnect line 436 and can be in contact with sidewalls of interconnect line 436. The elongated sides of interconnect lines 332A-332C and 436 can be along a Y-axis and the shorter sides of interconnect lines 332A-332C and 436 can be along an X-axis. FIG. 4A shows the cross-sectional view of interconnect lines 332A-332C and 436 along their shorter sides.

As discussed below, interconnect structure 401 can have interconnect lines of different dimensions, and, as resistivity of metals can vary with dimensions, interconnect structure 401 can have interconnect lines of different metals based on the dimensions to minimize the overall electrical resistance of interconnect structure 401. In some embodiments, unlike interconnect lines 332A-332C, interconnect line 436 can have (i) a cross-sectional area greater than about 400 nm² (e.g., about 420 nm² to about 2500 nm²) along its shorter side (e.g., along an X-axis), (ii) a tapered cross-sectional profile, along an XZ-plane, with widths decreasing from is top surface to its bottom surface, (iii) a width W3 of its top surface greater than a width W4 of its bottom surface, and (iv) widths W3 and W4 greater than about 20 nm. The structural profiles of interconnect line 436 can depend on the process of forming interconnect line 436 with the cross-sectional area greater than about 400 nm², as described in detail below.

In some embodiments, interconnect line 436 can include (i) a conductive metal nitride layer 436A, (ii) a metal liner 436B disposed on conductive metal nitride layer 436A, and (ii) a metal layer 436C disposed on metal liner 436B. In some embodiments, conductive metal nitride layer 436A can include TiN, AlN, TaN, or other suitable conductive metal nitrides. In some embodiments, metal liner 436B can serve as a diffusion barrier layer to prevent metal atoms of metal layer 436C from diffusing into underlying structures of GAA FET 100. In some embodiments, metal liner 436B can include cobalt or other suitable metal.

In some embodiments, metal layer 436C can include a metal (e.g., Cu) with a bulk resistivity less than about 4 μohm-cm to minimize electrical resistance in interconnect line 436. As the cross-sectional area of interconnect line 436 is greater than about 400 nm², a metal with a bulk resistivity greater than about 4 μohm-cm in metal layer 436C can increase the electrical resistance of interconnect line 436 compared to a metal (e.g., Ru, Al, Cr, Mo, Ti, or W) with a bulk resistivity greater than about 4 μohm-cm in metal layer 330B of interconnect lines 332A-332C with the cross-sectional areas less than about 400 nm². Thus, to minimize the overall electrical resistance of interconnect structure 401 with interconnect lines of different cross-sectional areas, interconnect structure 401 can have (i) the metal of metal layers 330B different from the metal of metal layer 436, (ii) the metal of metal layers 330B with an electron mean free path length shorter than that of the metal of metal layer 436, (iii) the metal of metal layers 330B with a bulk resistivity greater than that of the metal of metal layer 436, (iv) the metal of metal layers 330B with an electron mean free path length less than that of Cu, (v) the metal of metal layer 436 with an electron mean free path length equal to or greater than that of Cu, (vi) a metal of metal layers 330B with a bulk resistivity greater than about 4 μohm-cm, and (vii) a metal of metal layer 436 with a bulk resistivity less than about 4 μohm-cm.

Referring to FIG. 4B, in some embodiments, MLI structure 402 can be disposed on ILD layer 118C, instead of interconnect structure 401. In some embodiments, MLI structure 402 can include a stack of interconnect structures 401 and 403. Interconnect structures 401 can be electrically connected to each other though interconnect structure 403. In some embodiments, when an interconnect structure, such as interconnect structure 403 is stacked on interconnect structure 401, interconnect structure 401 can include (i) conductive capping layers 333 disposed directly on metal layers 330B of interconnect lines 332A-332C and (ii) a conductive capping layer 433 disposed directly on metal layer 436C of interconnect line 436. In some embodiments, conductive capping layers 333 can include a conductive material, such a nitride (e.g., ruthenium nitride) of the metal of metal layer 330B and conductive capping layers 433 can include a conductive material, such a nitride (e.g., copper nitride (CuN)) of the metal of metal layer 436C.

In some embodiments, interconnect structure 403 can include (i) ESL 335A, (ii) IMD layer 335B, and (iii) vias 335C and 435. ESL 335A can be disposed on dielectric fill layer 334B and portions of conductive capping layers 333 and 433 that are not covered by vias 335C and 435. IMD layer 335B can be disposed on ESL 335A and can surround vias 335C and 435. In some embodiments, top surfaces of IMD layer 335B and vias 335C and 435 can be substantially coplanar with respect to each other.

In some embodiments, via 335C can be disposed directly on conductive capping layer 333 that is on interconnect line 332B. Via 335C can electrically connect interconnect line 332B of bottom interconnect structure 401 to interconnect line 332B of top interconnect structure 401. Top surface of via 335C can be in direct contact with bottom surface of conductive metal nitride layer 330A of interconnect line 332B. Though one via 335C is shown in FIG. 4B, interconnect structure 403 can have other vias 335C (not visible in the cross-sectional view of FIG. 4B) to electrically connect interconnect lines 332A and/or 332C of top and bottom interconnect structures 401.

In some embodiments, via 435 can be disposed directly on conductive capping layer 433. Conductive capping layer 433 can provide a conductive interface between interconnect line 436 and via 435 to electrically connect interconnect line 436 to via 435 without forming via 435 directly on or within interconnect line 436. Via 435 is not formed directly on or within interconnect line 436 to prevent contamination of interconnect line 436 by any of the processing materials used in the formation of via 435. Via 435 can electrically connect interconnect line 436 of bottom interconnect structure 401 to interconnect line 436 of top interconnect structure 401. Top surface of via 435 can be in direct contact with bottom surface of conductive metal nitride layer 436A of interconnect line 436. In some embodiments, via 435 can include the same conductive material as via 335C. In some embodiments, via 435 can have (i) a tapered cross-sectional profile, along an XZ-plane, with widths increasing from its bottom surface to its top surface, and (ii) width W7 of its top surface greater than width W8 of its bottom surface.

Referring to FIG. 5A, in some embodiments, interconnect structure 501 can be disposed on ILD layer 118C, instead of interconnect structure 301. The discussion of interconnect structure 301 applies to interconnect structure 501, unless mentioned otherwise. In some embodiments, interconnect structure 501 can include (i) interconnect lines 332A-332C, (ii) IMD structure 534, and (ii) IMD structure 538. In some embodiments, IMD structure 534 can be disposed between interconnect lines 332A and 332B, which are separated from each other by a distance D1 greater than about 20 nm. On the other hand, in some embodiments, IMD structure 538 can be disposed between interconnect lines 332B and 332C, which are separated from each other by a distance D2 less than about 20 nm. In some embodiments, as distance D2 is less than distance D1, IMD structure 538 with a dielectric constant lower than a dielectric constant of IMD structure 334 is used between interconnect lines 332B and 332C to reduce the overall capacitance of interconnect structure 501.

In some embodiments, IMD structure 534 can include (i) dielectric capping layers 534A and 534B, and (ii) a dielectric fill layer 534C. Dielectric capping layers 534A and 534B can serve as a barrier layer for protecting interconnect lines 332A and 332B from thermal damage, environmental damage, and/or damage from processing chemicals during the formation of interconnect structure 501. In some embodiments, dielectric capping layers 534A and 534B can include an insulating material having silicon, oxygen, and/or carbon. In some embodiments, top surfaces of dielectric capping layers 534A and 534B, dielectric fill layer 534C, and metal layers 330B can be substantially coplanar with respect to each other.

In some embodiments, IMD structure 538 can include (i) a dielectric capping layer 538A, (ii) an air spacer 538B on dielectric capping layer 538A, (iii) an air sealing layer 538C disposed on dielectric capping layer 538A and air spacer 538B, and (iv) a dielectric fill layer 538D. Dielectric capping layer 538A can serve as a barrier layer for protecting interconnect lines 332B and 332C from thermal damage, environmental damage, and/or damage from processing chemicals during the formation of interconnect structure 501. In some embodiments, dielectric capping layer 538A can include an insulating material having silicon, oxygen, and/or carbon. In some embodiments, air spacer 538B can be a cavity filled with air formed between dielectric capping layer 538A and air sealing layer 538C. Air sealing layer 538C can seal the air cavity in air spacer 538B and prevent materials from entering into the cavity during the formation of layers overlying air spacer 538B. In some embodiments, a height H1 of air spacer 538B can be equal to or less than a height H2 of interconnect line 332B. In some embodiments, height H1 can be about 0.1 nm to about 29 nm, when height H2 is about 30 nm. In some embodiments, a ratio (H1:H2) between heights H1 and H2 can be about 0.1 to about 1. Within this range of height H1, the risk of damage to interconnect lines 332B and 332C by over-etching during subsequent formation of vias on interconnect lines 332B and/or 332C can be adequately reduced.

In some embodiments, dielectric fill layer 538D can include a low dielectric constant (e.g., dielectric constant less than about 3.0) and can include an insulating material having silicon, oxygen, carbon, and/or hydrogen. In some embodiments, top surfaces of dielectric capping layer 538A, air sealing layer 538C, dielectric fill layer 538D, and metal layers 330B can be substantially coplanar with respect to each other. In some embodiments, dielectric capping layer 538A and air sealing layer 538C can have a U-shaped cross-sectional profile along an X-axis. In some embodiments, the bottom surface of dielectric capping layer 538A can be in contact with ILD layer 118C and the bottom surface of air sealing layer 538C can be suspended over air spacer 538B. Though one IMD structure 538 is shown in FIG. 5A, interconnect structure 501 can have more than one IMD structure 538. For example, though IMD structure 538 is shown on one side of interconnect line 332C, IMD structures 538 can be disposed on both sides (not shown) of interconnect line 332C.

Referring to FIG. 5B, in some embodiments, MLI structure 502 can be disposed on ILD layer 118C, instead of interconnect structure 501. In some embodiments, MLI structure 502 can include a stack of interconnect structures 501 and 303. Interconnect structures 501 can be electrically connected to each other though interconnect structure 303. In some embodiments, interconnect structure 501 can include conductive capping layers 333 disposed directly on metal layers 330B of interconnect lines 332A-332C when an interconnect structure, such as interconnect structure 303 is stacked on interconnect structure 501. Via 335C of interconnect structure 303 can electrically connect interconnect line 332B of bottom interconnect structure 501 to interconnect line 332B of top interconnect structure 501. Though one via 335C is shown in FIG. 5B, interconnect structure 303 can have other vias 335C (not visible in the cross-sectional view of FIG. 5B) to electrically connect interconnect lines 332A and/or 332C of top and bottom interconnect structures 501.

Referring to FIG. 6A, in some embodiments, interconnect structure 601 can be disposed on ILD layer 118C, instead of interconnect structure 501. The discussion of interconnect structure 501 applies to interconnect structure 601, unless mentioned otherwise. In some embodiments, interconnect structure 601 can include (i) interconnect lines 332A-332C, (ii) interconnect line 436, (iii) IMD structure 534, and (iv) IMD structure 538. In some embodiments, IMD structure 534 can surround interconnect line 436 and can be in contact with sidewalls of interconnect line 436.

Referring to FIG. 6B, in some embodiments, MLI structure 602 can be disposed on ILD layer 118C, instead of interconnect structure 601. In some embodiments, MLI structure 602 can include a stack of interconnect structures 601 and 403. Interconnect structures 601 can be electrically connected to each other though interconnect structure 403. In some embodiments, when an interconnect structure, such as interconnect structure 403 is stacked on interconnect structure 601, interconnect structure 601 can include (i) conductive capping layers 333 disposed directly on metal layers 330B of interconnect lines 332A-332C and (ii) conductive capping layer 433 disposed directly on metal layer 436C of interconnect line 436.

Via 335C of interconnect structure 403 can electrically connect interconnect line 332B of bottom interconnect structure 601 to interconnect line 332B of top interconnect structure 601. Top surface of via 335C can be in direct contact with bottom surface of conductive metal nitride layer 330A of interconnect line 332B. Though one via 335C is shown in FIG. 6B, interconnect structure 403 can have other vias 335C (not visible in the cross-sectional view of FIG. 6B) to electrically connect interconnect lines 332A and/or 332C of top and bottom interconnect structures 601. Via 435 of interconnect structure 403 can electrically connect interconnect line 436 of bottom interconnect structure 601 to interconnect line 436 of top interconnect structure 601. Top surface of via 435 can be in direct contact with bottom surface of conductive metal nitride layer 436A of interconnect line 436.

Referring to FIG. 6C, in some embodiments, MLI structure 602 can include a stack of interconnect structures 601, 303, 501, instead of the stack of interconnect structures 601 and 403 of FIG. 6B. Interconnect structure 501 can be disposed on interconnect structure 303, as shown in FIG. 6C, instead of interconnect structure 601 on interconnect structure 403, as shown in FIG. 6B. Referring to FIG. 6D, in some embodiments, MLI structure 602 can include a stack of interconnect structures 601, 403, 401, instead of the stack of interconnect structures 601 and 403 of FIG. 6B. Interconnect structure 401 can be disposed on interconnect structure 403, as shown in FIG. 6D, instead of interconnect structure 601 on interconnect structure 403, as shown in FIG. 6B. Referring to FIG. 6E, in some embodiments, MLI structure 602 can include a stack of interconnect structures 601, 303, 301, instead of the stack of interconnect structures 601 and 403 of FIG. 6B. Interconnect structure 301 can be disposed on interconnect structure 303, as shown in FIG. 6E, instead of interconnect structure 601 on interconnect structure 403, as shown in FIG. 6B.

Referring to FIG. 3B, instead of the stack of interconnect structures 301 and 303, MLI structure 302 can include (i) a stack (not shown) of interconnect structures 301, 303, 401, (ii) a stack (not shown) of interconnect structures 301, 303, 501, or (iii) a stack (not shown) of interconnect structures 301, 303, 601, according to some embodiments. That is, instead of interconnect structure 301 on interconnect structure 303 of FIG. 3B, interconnect structure 401, 501, or 601 can be disposed on interconnect structure 303 of FIG. 3B.

Referring to FIG. 4B, instead of the stack of interconnect structures 401 and 403, MLI structure 402 can include (i) a stack (not shown) of interconnect structures 401, 403, 301, (ii) a stack (not shown) of interconnect structures 401, 403, 501, or (iii) a stack (not shown) of interconnect structures 401, 403, 601, according to some embodiments. That is, instead of interconnect structure 401 on interconnect structure 403 of FIG. 4B, interconnect structure 301, 501, or 601 can be disposed on interconnect structure 403 of FIG. 4B.

Referring to FIG. 5B, instead of the stack of interconnect structures 501 and 303, MLI structure 502 can include (i) a stack (not shown) of interconnect structures 501, 303, 301, (ii) a stack (not shown) of interconnect structures 501, 303, 401, or (iii) a stack (not shown) of interconnect structures 501, 303, 601, according to some embodiments. That is, instead of interconnect structure 501 on interconnect structure 303 of FIG. 5B, interconnect structure 301, 401, or 601 can be disposed on interconnect structure 303 of FIG. 5B.

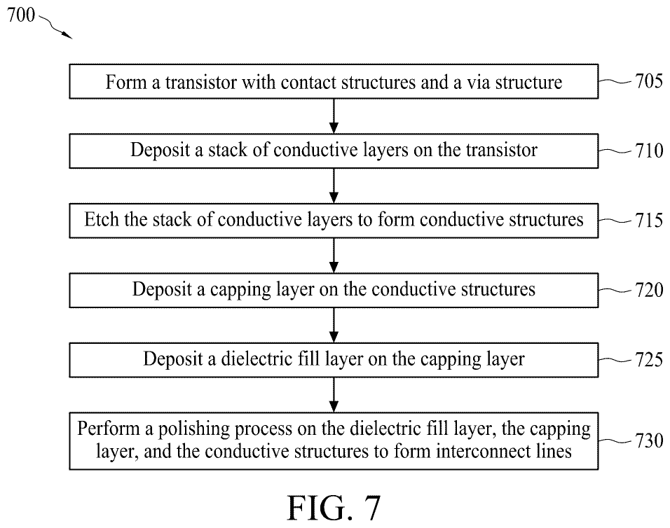

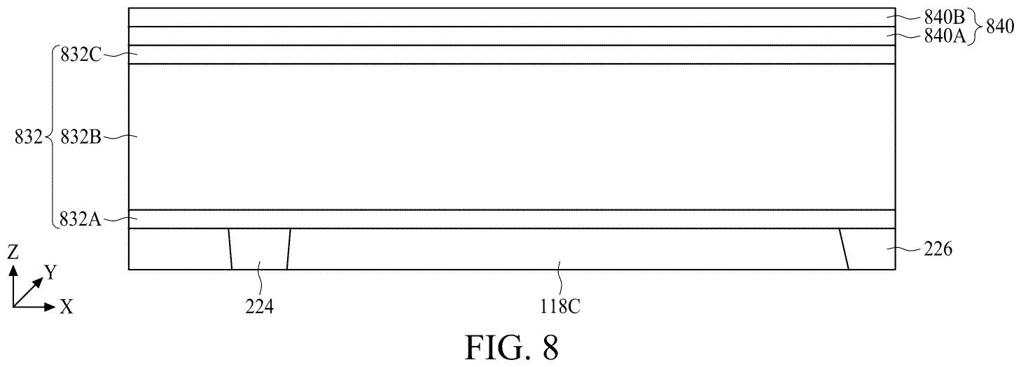

FIG. 7 is a flow diagram of an example method 700 for fabricating interconnect structure 301 on GAA FET 100, according to some embodiments. For illustrative purposes, the operations illustrated in FIG. 7 will be described with reference to the example fabrication process for fabricating interconnect structure 301 on GAA FET 100 as illustrated in FIGS. 2 and 8-12. FIGS. 8-12 are cross-sectional views of interconnect structure 301 on GAA FET 100 at various stages of its fabrication, according to some embodiments. Operations can be performed in a different order or not performed depending on specific applications. It should be noted that method 700 may not produce a complete interconnect structure 301. Accordingly, it is understood that additional processes can be provided before, during, and after method 700, and that some other processes may only be briefly described herein. The discussion of elements in FIGS. 1-3 and 8-12 with the same annotations applies to each other, unless mentioned otherwise.

Referring to FIG. 7, in operation 705, a transistor with contact structures and via structure is formed on a substrate. For example, as shown in FIG. 2, GAA FET 100 having S/D contact structure 220, gate contact structure 226, and via structure 224 are formed on substrate 102.

Referring to FIG. 7, in operation 710, a stack of conductive layers are deposited on the transistor. For example, as described with reference to FIG. 8, a stack of conductive layers 832 is formed. In some embodiments, the formation of stack of conductive layers 832 can include sequential operations of (i) depositing a first metal nitride layer 832A on GAA FET 100, as shown in FIG. 8, (ii) depositing a metal layer 832B on first metal nitride layer 832A, as shown in FIG. 8, and (iii) depositing a second metal nitride layer 832C on metal layer 832B, as shown in FIG. 8. In some embodiments, depositing first and second metal nitride layers 832A and 832C can include depositing a TiN layer, a TaN layer, or an AlN layer using a chemical vapor deposition (CVD) process, an atomic layer deposition (ALD) process, or other suitable deposition process. In some embodiments, depositing metal layer 832B can include depositing a metal with an electron mean free path length that is shorter than an electron mean free path length (e.g., about 40 nm) of Cu. In some embodiments, depositing metal layer 832B can include depositing a layer of Ru, Al, Cr, Mo, Ti, or W in a CVD process, an ALD process, or other suitable metal deposition process.

In some embodiments, the formation of stack of conductive layers 832 can be followed by the formation of a stack of hard mask layers 840. The formation of stack of hard mask layers 840 can include depositing a nitride-based hard mask layer 840A (e.g., a SiN layer) on second metal nitride layer 832C and depositing an oxide-based hard mask layer 840A (e.g., a SiO₂ layer) on nitride-based hard mask layer 840A, as shown in FIG. 8.

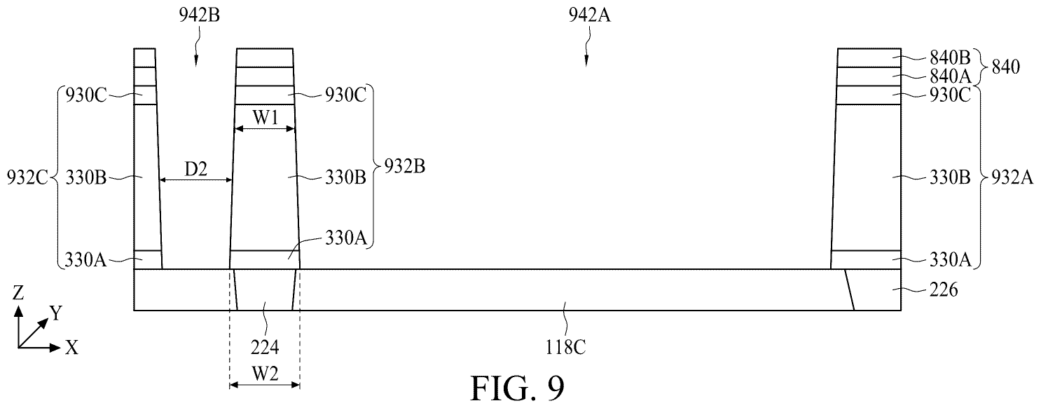

Referring to FIG. 7, in operation 715, the stack of conductive layers is etched to form conductive structures. For example, as described with reference to FIG. 9, stack of conductive layers 832 is etched to form conductive structures 932A-932C, each having conductive metal nitride layer 330A, metal layer 330B, and metal nitride layer 930C. In some embodiments, the etching of stack of conductive layers 832 can include performing a plasma-based etch process (e.g., reactive ion etch (RIE) process) using a mixture of oxygen and chlorine-based or fluorine-based etching gas on the structure of FIG. 8. Besides conductive structures 932A-932C, openings 942A and 942B between conductive structures 932A-932C are formed and portions of the top surface of ILD layer 118C are exposed in openings 942A and 942B, as shown in FIG. 9. As a result of the etch process, each of conductive structures 932A-932C can have (i) a tapered cross-sectional profile, along an XZ-plane, with widths increasing from its top surface to its bottom surface, and (ii) width W1 of its top surface smaller than width W2 of its bottom surface.

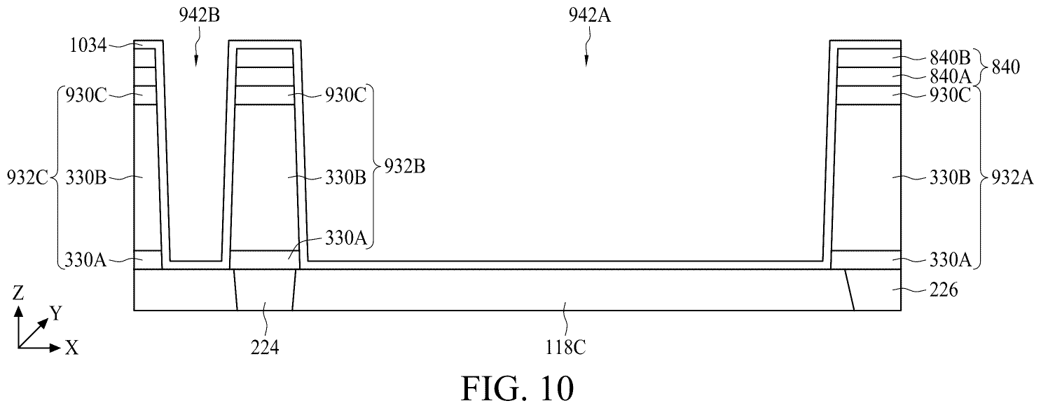

Referring to FIG. 7, in operation 720, a capping layer is deposited on the conductive structures. For example, as described with reference to FIG. 10, a capping layer 1034 is deposited on conductive structures 932A-932C and on the exposed portions of the top surface of ILD layer 118C in openings 942A and 942B. In some embodiments, the deposition of capping layer 1034 can include depositing about 1 nm to about 2 nm thick layer of an insulating material having silicon, oxygen, and/or carbon on the structure of FIG. 9 in a CVD process, an ALD process, or other suitable deposition process.

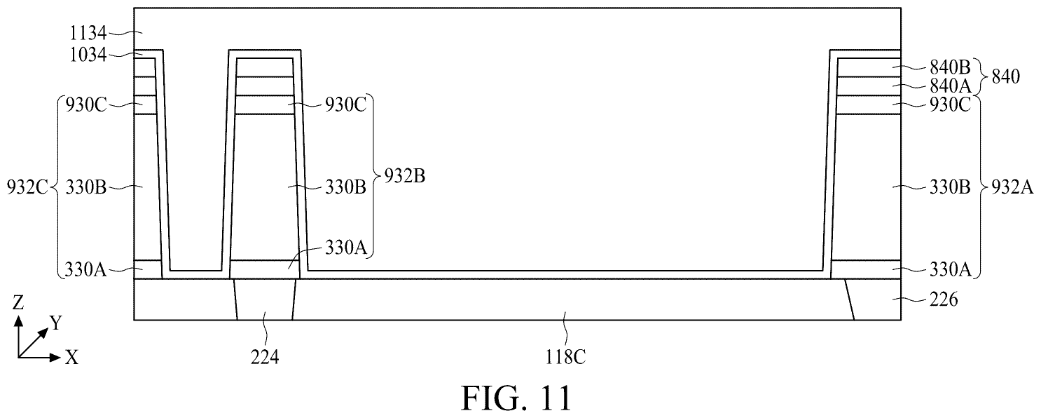

Referring to FIG. 7, in operation 725, a dielectric fill layer is deposited on the capping layer. For example, as described with reference to FIG. 11, a dielectric fill layer 1134 is deposited on capping layer 1034. In some embodiments, the deposition of dielectric fill layer 1134 can include depositing a layer of insulating material having silicon, oxygen, carbon, and/or hydrogen and a dielectric constant less than about 3.0 on the structure of FIG. 10 in a CVD process, an ALD process, or other suitable deposition process. The deposition of dielectric fill layer 1134 after the formation of conductive structures 932A-932C can prevent or minimize the structural damage to dielectric fill layer 1134, which forms IMD structure 334 in subsequent processing operations.

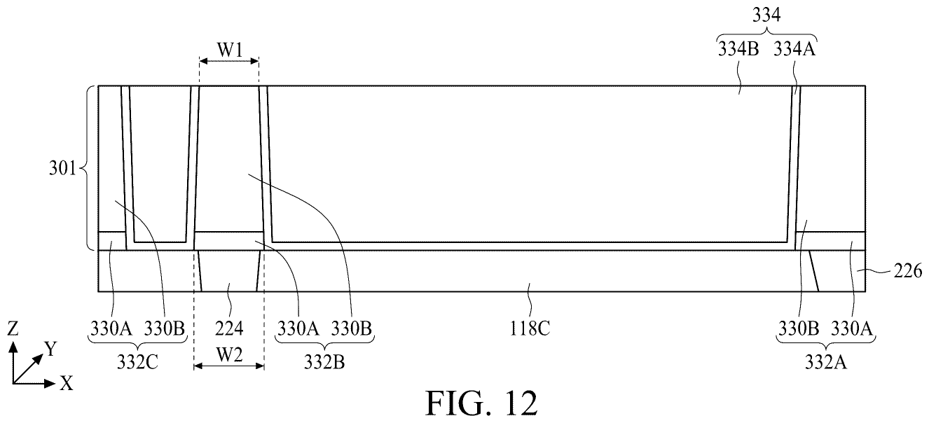

Referring to FIG. 7, in operation 730, a polishing process is performed on the dielectric fill layer, the capping layer, and the conductive structures to form interconnect lines. For example, as described with reference to FIG. 12, a chemical mechanical polishing (CMP) process is performed on dielectric fill layer 1134, capping layer 1034, stack of hard mask layers 840, and conductive structures 932A-932C to form interconnect lines 332A-322C and IMD structures 334.

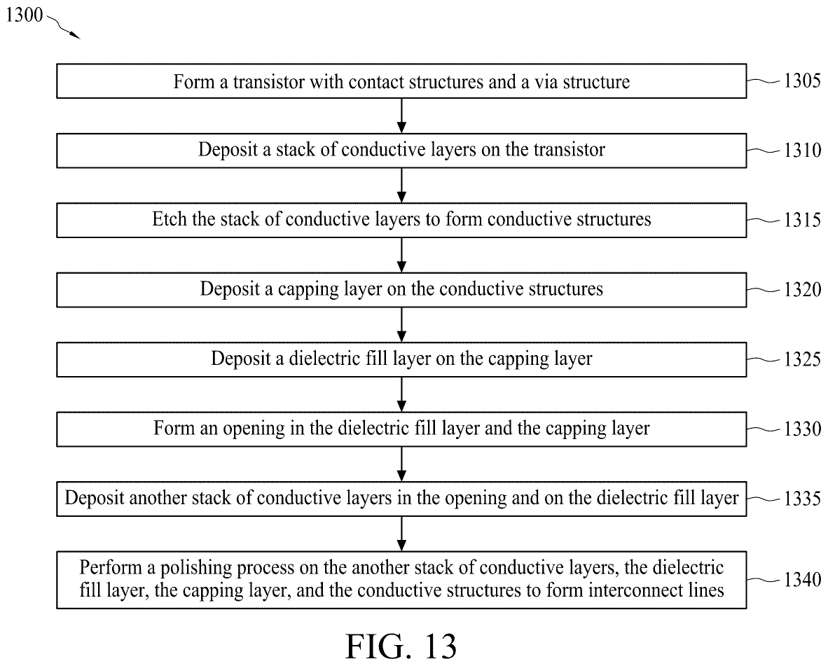

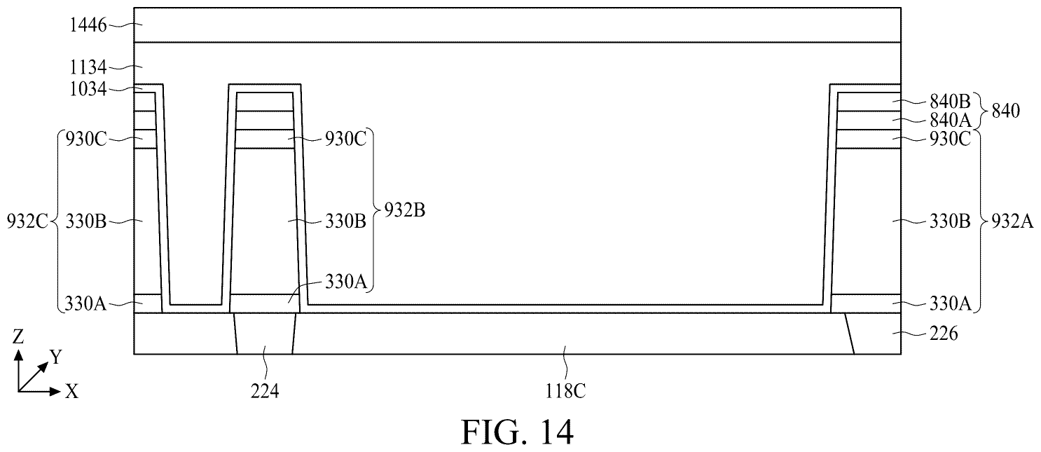

FIG. 13 is a flow diagram of an example method 1300 for fabricating interconnect structure 401 on GAA FET 100, according to some embodiments. For illustrative purposes, the operations illustrated in FIG. 13 will be described with reference to the example fabrication process for fabricating interconnect structure 401 on GAA FET 100 as illustrated in FIGS. 14-17. FIGS. 14-17 are cross-sectional views of interconnect structure 401 on GAA FET 100 at various stages of its fabrication, according to some embodiments. Operations can be performed in a different order or not performed depending on specific applications. It should be noted that method 1300 may not produce a complete interconnect structure 401. Accordingly, it is understood that additional processes can be provided before, during, and after method 1300, and that some other processes may only be briefly described herein. The discussion of elements in FIGS. 1-4, 8-12, and 14-17 with the same annotations applies to each other, unless mentioned otherwise.

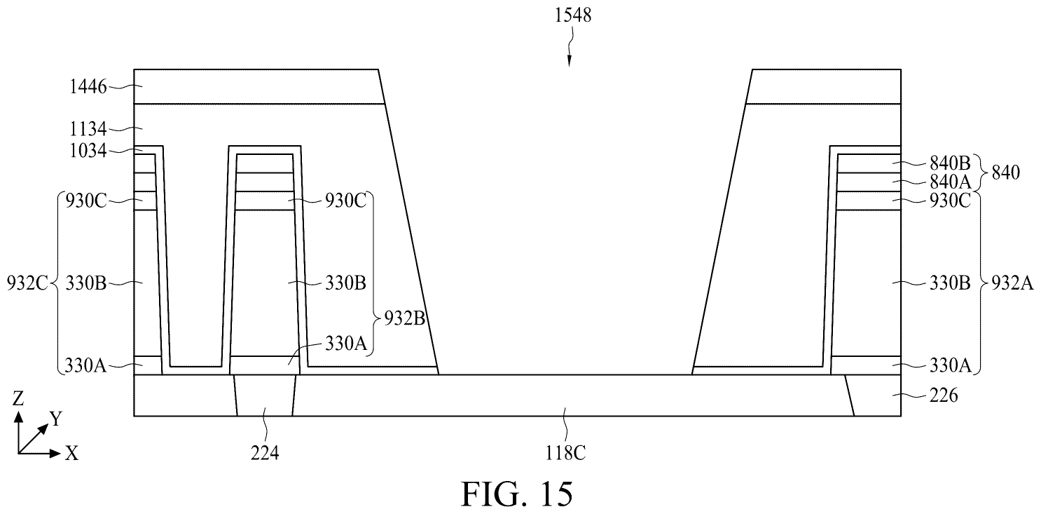

Referring to FIG. 13, operations 1305-1325 are similar to operations 705-725 of FIG. 7. After operation 1325, a structure similar to the structure of FIG. 11 is formed. In some embodiments, a hard mask layer 1446 (e.g., a SiN layer) can be formed on the structure of FIG. 11 to form the structure of FIG. 14. The subsequent operation 1330 of FIG. 13 is performed on the structure of FIG. 14, as described below with reference to FIG. 15.

Referring to FIG. 13, in operation 1330, an opening is formed in the dielectric fill layer and the capping layer. For example, as described with reference to FIG. 15, an opening 1548 is formed in hard mask layer 1446, dielectric fill layer 1134, and capping layer 1034. A portion of the top surface of ILD layer 118C can be exposed in opening 1548, as shown in FIG. 15. In some embodiments, a dry etch process or a wet etch process can be used to remove portions of hard mask layer 1446, dielectric fill layer 1134, and capping layer 1034 to form opening 1548.

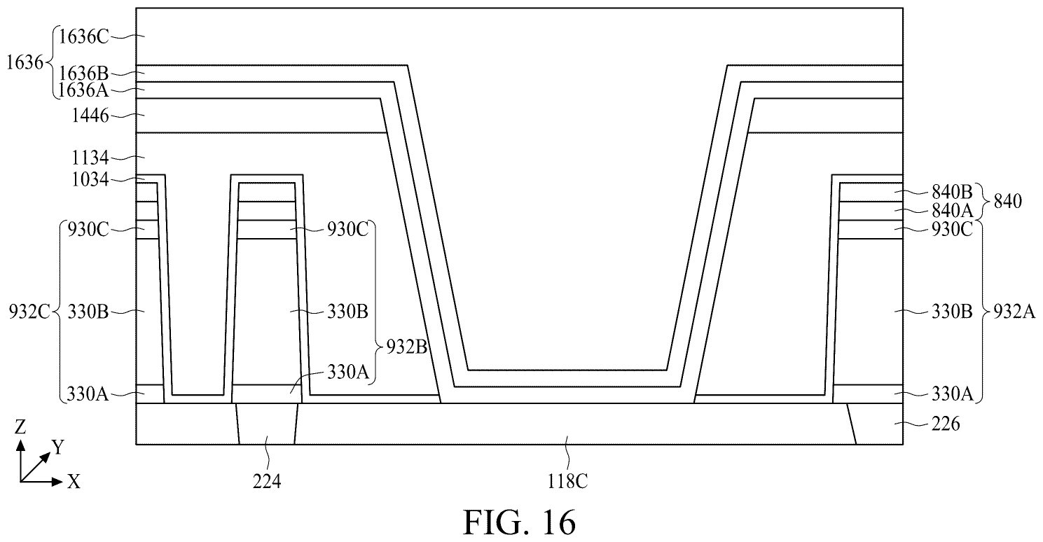

Referring to FIG. 13, in operation 1335, another stack of conductive layers is deposited in the opening and on the dielectric fill layer. For example, as described with reference to FIG. 16, stack of conductive layers 1636 is formed in opening 1548 and on dielectric fill layer 1134. In some embodiments, the formation of stack of conductive layers 1636 can include sequential operations of (i) depositing a metal nitride layer 1636A in opening 1548 and on hard mask layer 1446, as shown in FIG. 16, (ii) depositing a metal layer 1636B on metal nitride layer 1636A, as shown in FIG. 16, and (iii) depositing a metal fill layer 1636C on metal layer 1636B to fill opening 1548, as shown in FIG. 16. In some embodiments, depositing metal nitride layer 1636A can include depositing a TiN layer, a TaN layer, or an AlN layer using a CVD process, an ALD process, or other suitable deposition process. In some embodiments, depositing metal layer 1636B can include depositing a Co layer using a CVD process, an ALD process, or other suitable deposition process. In some embodiments, depositing metal fill layer 1636C can include depositing a metal (e.g., Cu) with a bulk resistivity less than about 4 μohm-cm in a CVD process, an ALD process, electro-chemical plating process, or other suitable metal deposition process.

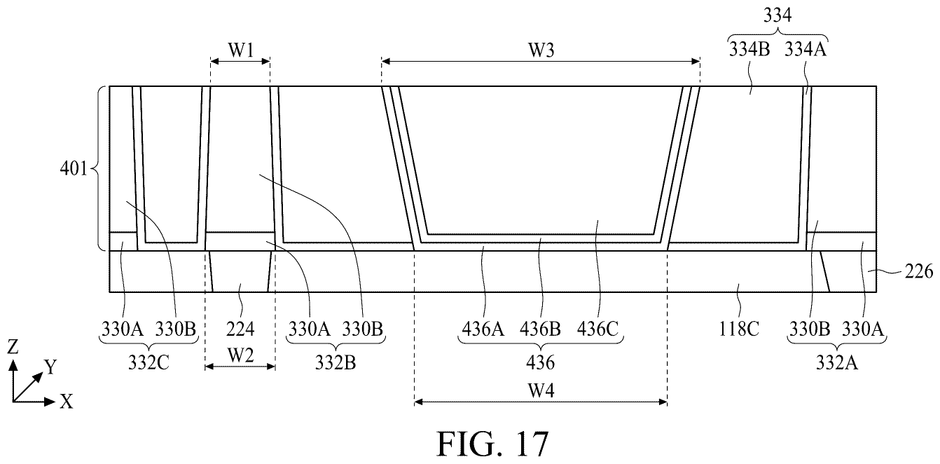

Referring to FIG. 13, in operation 1340, a polishing process is performed on the another stack of conductive layers, the dielectric fill layer, the capping layer, and the conductive structures to form interconnect lines. For example, as described with reference to FIG. 17, a CMP process is performed on stack of conductive layers 1636, hard mask layer 1446, dielectric fill layer 1134, capping layer 1034, stack of hard mask layers 840, and conductive structures 932A-932C to form interconnect lines 332A-322C, interconnect line 436, and IMD structures 334.

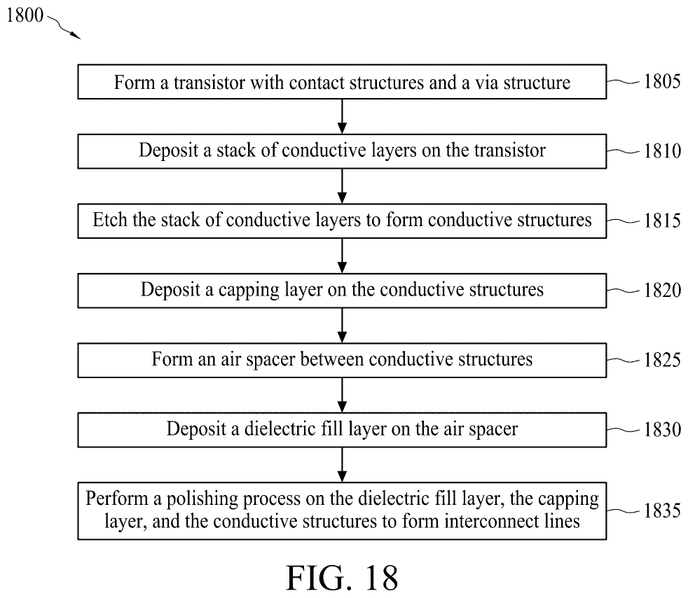

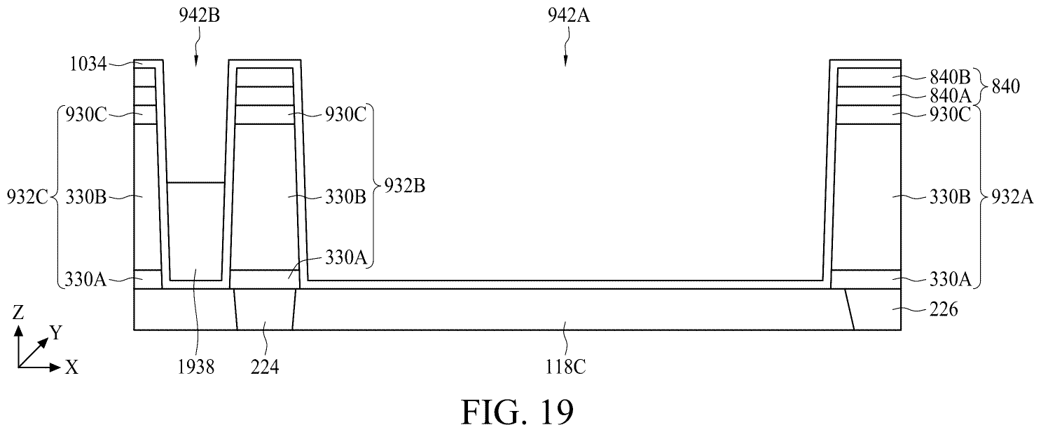

FIG. 18 is a flow diagram of an example method 1800 for fabricating interconnect structure 501 on GAA FET 100, according to some embodiments. For illustrative purposes, the operations illustrated in FIG. 18 will be described with reference to the example fabrication process for fabricating interconnect structure 501 on GAA FET 100 as illustrated in FIGS. 19-23. FIGS. 19-23 are cross-sectional views of interconnect structure 501 on GAA FET 100 at various stages of its fabrication, according to some embodiments. Operations can be performed in a different order or not performed depending on specific applications. It should be noted that method 1800 may not produce a complete interconnect structure 501. Accordingly, it is understood that additional processes can be provided before, during, and after method 1800, and that some other processes may only be briefly described herein. The discussion of elements in FIGS. 1-5, 8-12, 14-17, and 19-23 with the same annotations applies to each other, unless mentioned otherwise.

Referring to FIG. 18, operations 1805-1820 are similar to operations 705-720 of FIG. 7. After operation 1820, a structure similar to the structure of FIG. 10 is formed. The subsequent operation 1825 of FIG. 18 is performed on the structure of FIG. 10, as described below with reference to FIG. 19.

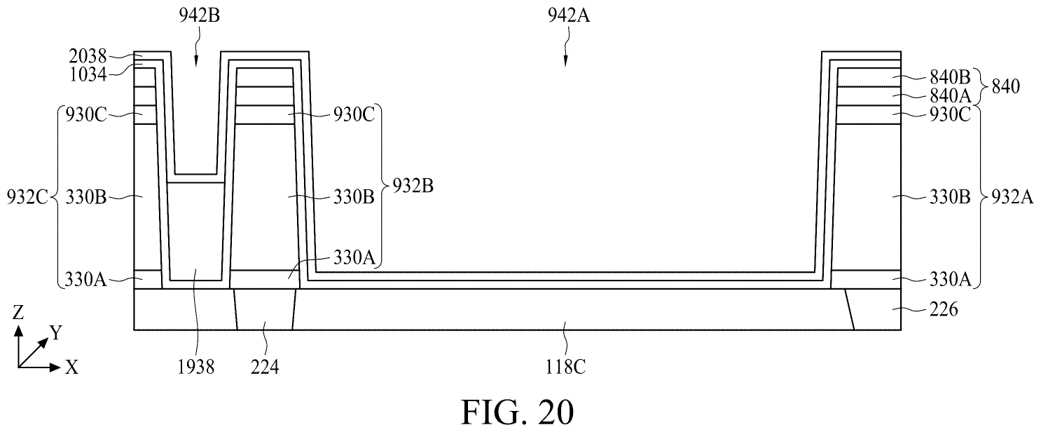

Referring to FIG. 18, in operation 1825, an air spacer is formed between the conductive structures. For example, as described with reference to FIGS. 19-21, air spacer 538B is formed between conductive structures 932B and 932C. The formation of air spacer 538B can include sequential operations of (i) forming a sacrificial layer 1938 on a portion of capping layer 1034 in opening 942B between conductive structures 932B and 932C, as shown in FIG. 19, (ii) depositing a dielectric layer 2038 on sacrificial layer 1938 and capping layer 1034, as shown in FIG. 20, and (iii) removing sacrificial layer 1938 to form air spacer 538B between dielectric layer 2038 and capping layer 1034.

In some embodiments, the formation of sacrificial layer 1938 can include forming a polymer layer on the portion of capping layer 1034 in opening 942B. In some embodiments, the formation of polymer layer 1938 can include a spin-coating a polymer material on the structure of FIG. 19. As the dimensions of opening 942B is smaller than opening 942A, portions of the polymer material in opening 942A can be spun off and portions of the polymer material in opening 942B can be retained during the spin-coating process.

In some embodiments, the removal of sacrificial layer 1938 can including performing (i) an anneal process at a temperature of about 200° C. to about 400° C. on the structure of FIG. 20 or (ii) an oxidation process at a temperature of about 200° C. to about 400° C. on the structure of FIG. 20. In some embodiments, the anneal process can decompose the material (e.g., polymer material) of sacrificial layer 1938 and the gaseous byproducts formed as a result of the decomposition can diffuse out through dielectric layer 2038. In some embodiments, the oxidation process can include exposing the structure of FIG. 20 to an oxygen gas. The oxygen gas can react with the material (e.g., polymer material) of sacrificial layer 1938 and form gaseous byproducts (e.g., carbon oxide (CO₂) and hydrogen), which can diffuse out through dielectric layer 2038. In some embodiments, the deposition of dielectric layer 2038 can include depositing an insulating material that is permeable to the oxygen gas introduced during the oxidation process and to the gaseous byproducts from during the removal of sacrificial layer 1938. In some embodiments, the deposition of the insulating material of dielectric layer 2038 can include depositing about 0.5 nm to about 5 nm thick layer of the insulating material having silicon, oxygen, and/or carbon in a CVD process, an ALD process, or other suitable deposition process. Within this thickness range of dielectric layer 2038, dielectric layer 2038 can have adequate mechanical strength for supporting overlying layers, such as dielectric fill layer 538D without compromising the removal of sacrificial layer 1938. Below 0.5 nm thickness, dielectric layer 2038 may not have adequate mechanical strength to support the overlying layers. On the other hand, above 5 nm thickness, the gaseous byproducts formed during the removal of sacrificial layer 1938 may not adequately diffuse out through dielectric layer 2038.

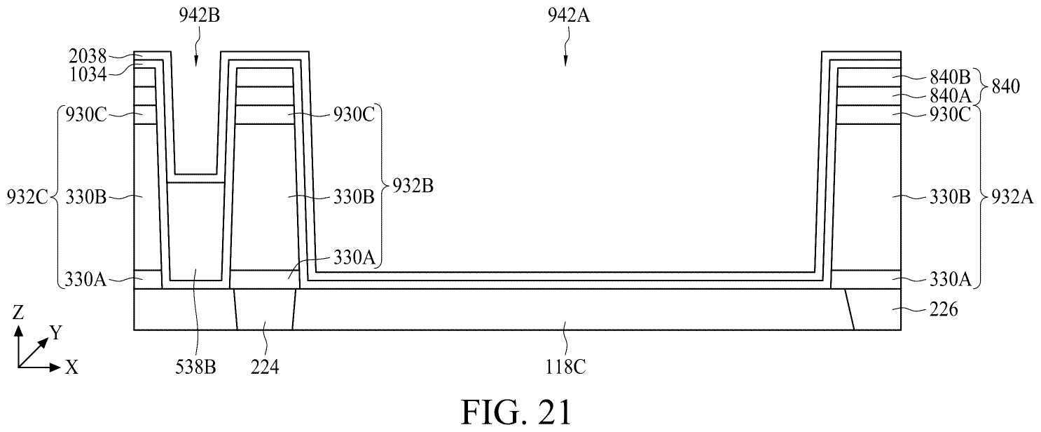

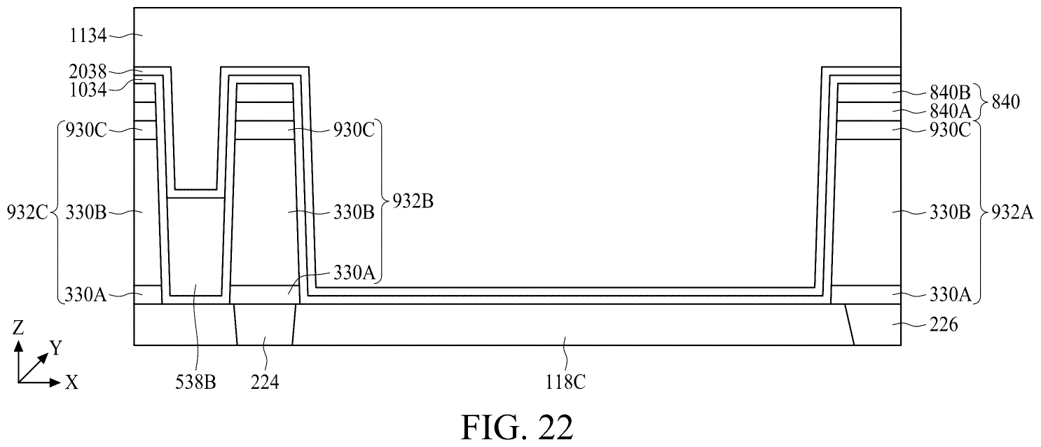

Referring to FIG. 18, in operation 1830, a dielectric fill layer is deposited on the air spacer. For example, as described with reference to FIG. 22, dielectric fill layer 1134 is deposited on air spacer 538B. In some embodiments, the deposition of dielectric fill layer 1134 can include depositing a layer of insulating material having silicon, oxygen, carbon, and/or hydrogen and a dielectric constant less than about 3.0 to fill openings 942A and 942B in FIG. 21, as shown in FIG. 22.

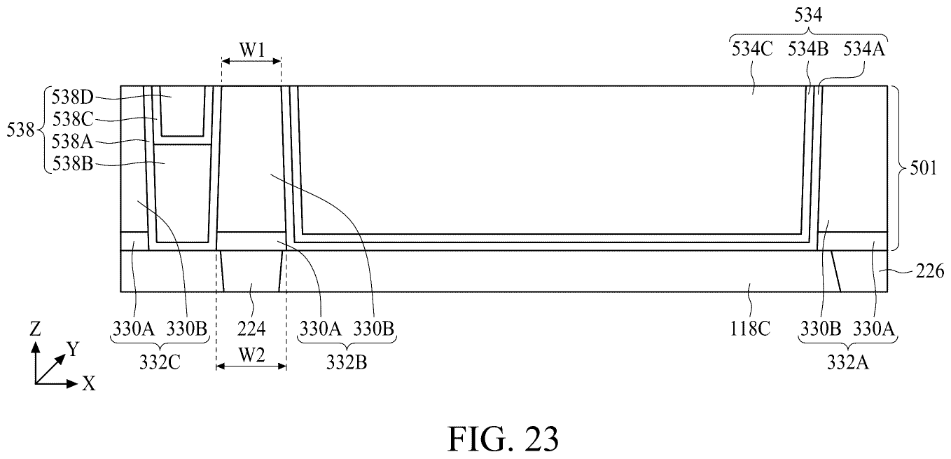

Referring to FIG. 18, in operation 1835, a polishing process is performed on the dielectric fill layer, the capping layer, and the conductive structures to form interconnect lines. For example, as described with reference to FIG. 23, a CMP process is performed on dielectric fill layer 1134, dielectric layer 2038, capping layer 1034, stack of hard mask layers 840, and conductive structures 932A-932C to form interconnect lines 332A-322C, IMD structure 534, and IMD structure 538.

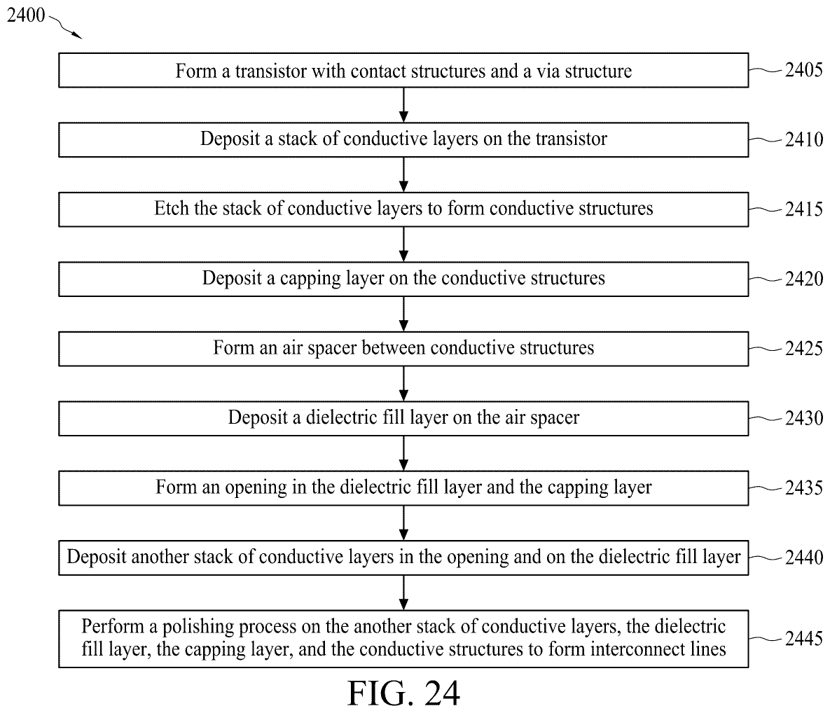

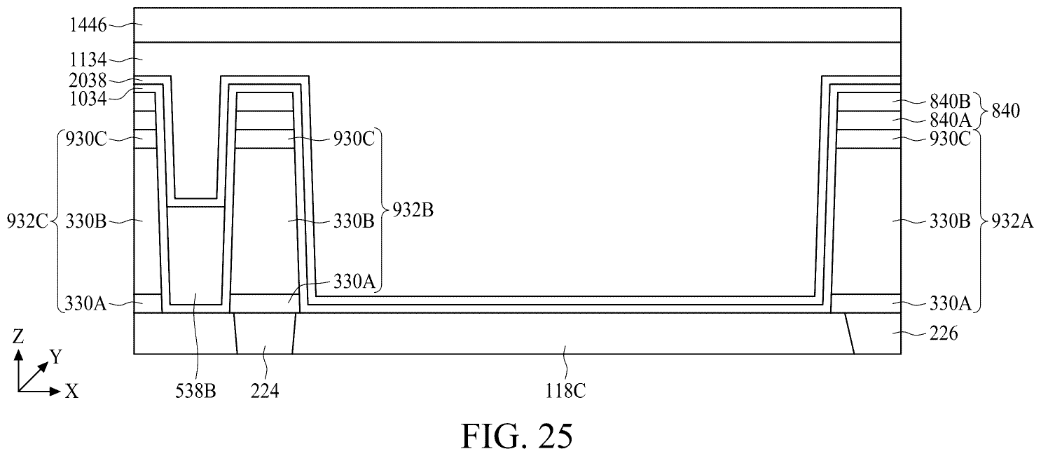

FIG. 24 is a flow diagram of an example method 2400 for fabricating interconnect structure 601 on GAA FET 100, according to some embodiments. For illustrative purposes, the operations illustrated in FIG. 24 will be described with reference to the example fabrication process for fabricating interconnect structure 601 on GAA FET 100 as illustrated in FIGS. 25-28. FIGS. 25-28 are cross-sectional views of interconnect structure 601 on GAA FET 100 at various stages of its fabrication, according to some embodiments. Operations can be performed in a different order or not performed depending on specific applications. It should be noted that method 2400 may not produce a complete interconnect structure 601. Accordingly, it is understood that additional processes can be provided before, during, and after method 2400, and that some other processes may only be briefly described herein. The discussion of elements in FIGS. 1-5, 8-12, 14-17, 19-23, and 25-28 with the same annotations applies to each other, unless mentioned otherwise.

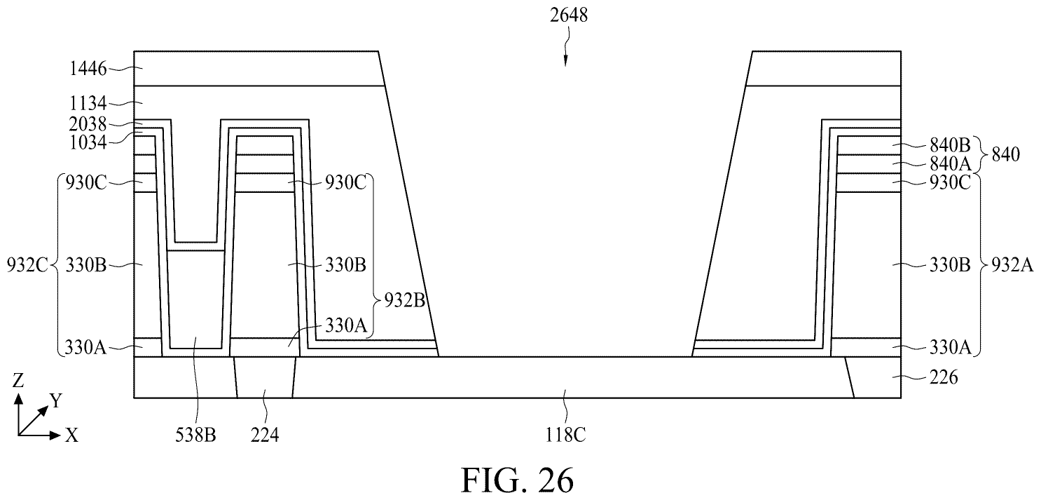

Referring to FIG. 24, operations 2405-2430 are similar to operations 1805-1830 of FIG. 18. After operation 2430, a structure similar to the structure of FIG. 22 is formed. In some embodiments, hard mask layer 1446 can be formed on the structure of FIG. 22 to form the structure of FIG. 25. The subsequent operation 2435 of FIG. 24 is performed on the structure of FIG. 25, as described below with reference to FIG. 26.

Referring to FIG. 24, in operation 2435, an opening is formed in the dielectric fill layer and the capping layer. For example, as described with reference to FIG. 26, an opening 2648 is formed in hard mask layer 1446, dielectric fill layer 1134, dielectric layer 2038, and capping layer 1034. A portion of the top surface of ILD layer 118C can be exposed in opening 2648, as shown in FIG. 26. In some embodiments, a dry etch process or a wet etch process can be used to remove portions of hard mask layer 1446, dielectric fill layer 1134, dielectric layer 2038, and capping layer 1034 to form opening 1548.

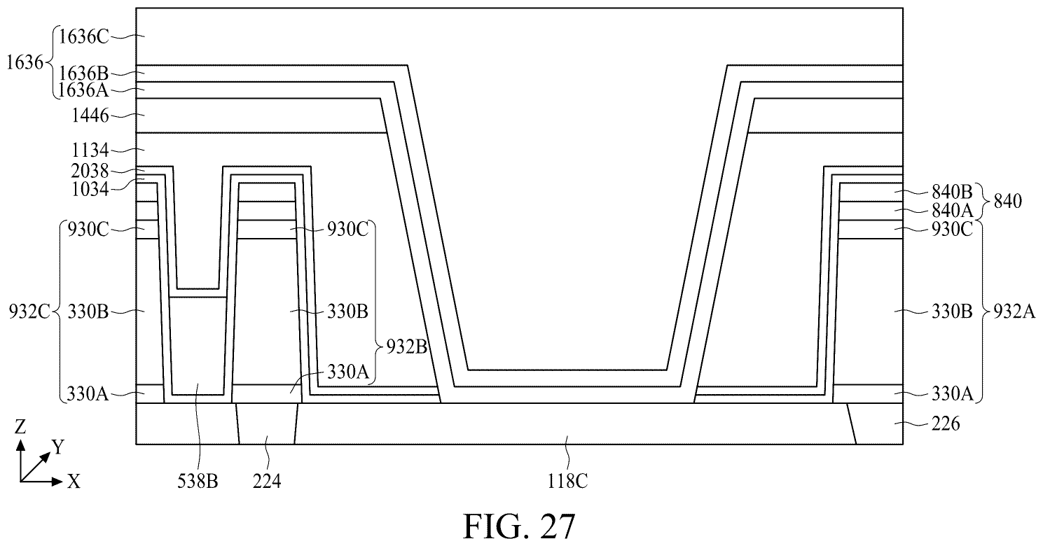

Referring to FIG. 24, in operation 2440, another stack of conductive layers is deposited in the opening and on the dielectric fill layer. For example, as shown in FIG. 27, stack of conductive layers 1636 is formed in opening 2648 and on dielectric fill layer 1134 in the process described in operation 1335 of FIG. 13.

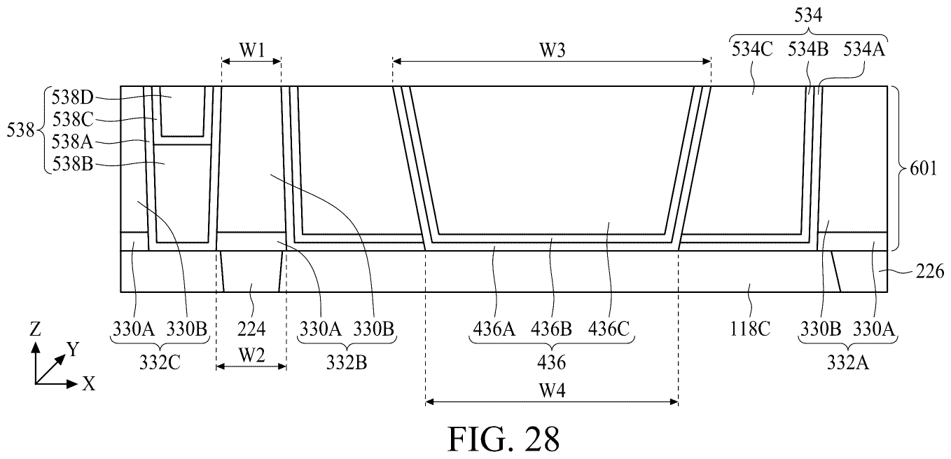

Referring to FIG. 24, in operation 2445, a polishing process is performed on the another stack of conductive layers, the dielectric fill layer, the capping layer, and the conductive structures to form interconnect lines. For example, as described with reference to FIG. 28, a CMP process is performed on stack of conductive layers 1636, hard mask layer 1446, dielectric fill layer 1134, dielectric layer 2038, capping layer 1034, stack of hard mask layers 840, and conductive structures 932A-932C to form interconnect lines 332A-322C, interconnect line 436, IMD structure 534, and IMD structure 538.

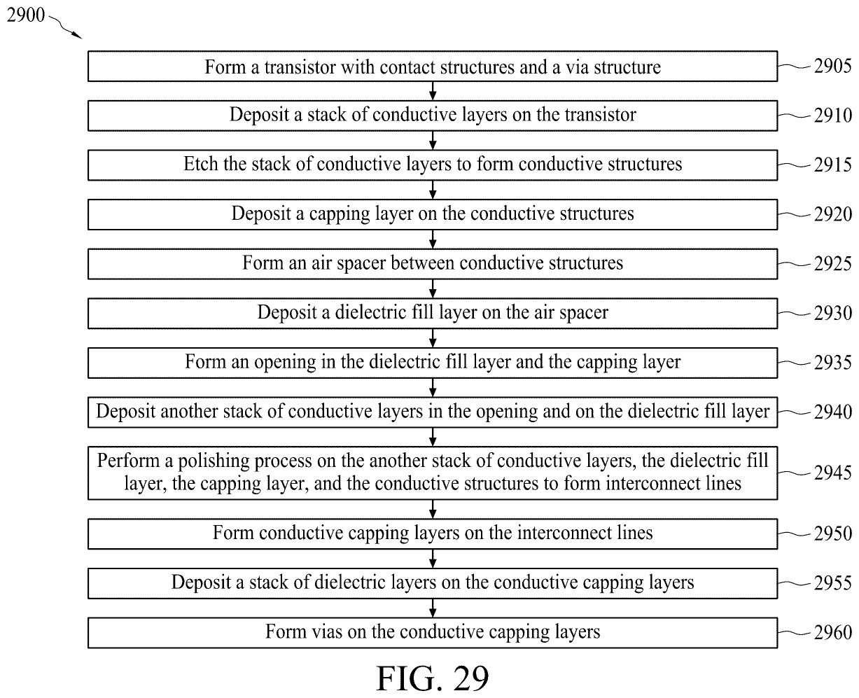

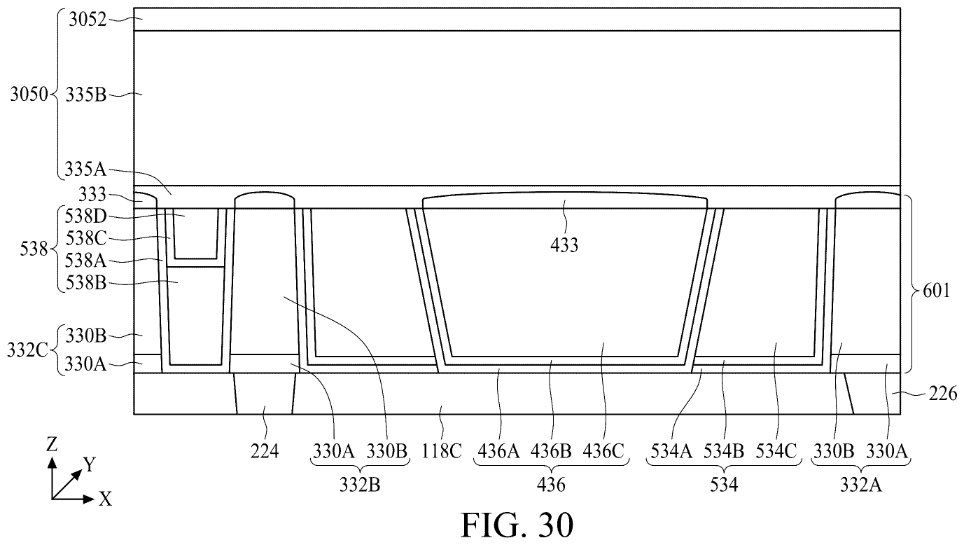

FIG. 29 is a flow diagram of an example method 2900 for fabricating MLI structure 602 on GAA FET 100, according to some embodiments. For illustrative purposes, the operations illustrated in FIG. 29 will be described with reference to the example fabrication process for fabricating MLI structure 602 on GAA FET 100 as illustrated in FIGS. 30-34. FIGS. 30-34 are cross-sectional views of MLI structure 602 on GAA FET 100 at various stages of its fabrication, according to some embodiments. Operations can be performed in a different order or not performed depending on specific applications. It should be noted that method 2900 may not produce a complete MLI structure 602. Accordingly, it is understood that additional processes can be provided before, during, and after method 2900, and that some other processes may only be briefly described herein. The discussion of elements in FIGS. 1, 2, 3A-3B, 4A-4B, 5A-5B, 6A-6E, 8-12, 14-17, 19-23, and 25-28 with the same annotations applies to each other, unless mentioned otherwise.

Referring to FIG. 29, operations 2905-2945 are similar to operations 2405-2445 of FIG. 24, which forms interconnect structure 601. After operation 2945, a structure similar to the structure of FIG. 28 is formed. The subsequent operation 2950 of FIG. 29 is performed on the structure of FIG. 28, as described below with reference to FIG. 30.

Referring to FIG. 29, in operation 2950, conductive capping layers are formed on the interconnect lines. For example, as described with reference to FIG. 30, conductive capping layers 333 are formed on interconnect lines 332A-332C and conductive capping layer 433 is formed on interconnect line 436. In some embodiments, the formation of conductive capping layers 333 and 433 can include performing a nitridation process on the structure of FIG. 28 to convert top portions of metal layers 330B and 436C into conductive capping layers 333 and 433. As a result, conductive capping layers 333 and 433 can be a nitride of the metals of metal layers 330B and 436C, respectively. Both conductive capping layers 333 and 433 can be formed at the same time during the nitridation process. The nitridation process can include a high density and low bombardment energy plasma (e.g., between about 25 eV and about 100 eV) of nitrogen gas, ammonia (NH3) gas, or nitrous oxide gas. The plasma can be generated using a high plasma source power (e.g., between about 400 W and about 2000 W) and a low bias power (e.g., between about 600 W and 3000 W).

In some embodiments, the formation of conductive capping layers 333 and 433 can include depositing conductive nitride layers on metal layers 330B and 436C in a CVD process, an ALD process, or other suitable metal deposition process. In some embodiments, the same conductive nitride layers (e.g., TaN, TiN, RuN, CuN, AlN, or CON) can be deposited at the same time on metal layers 330B and 436C using the same deposition process or different conductive nitride layers can be deposited at different times on metal layers 330B and 436C using different deposition processes. In some embodiments, dielectric fill layers 534C and 538D can be protected with a masking layer (e.g., a photoresist layer; not shown) during the nitridation process.

Referring to FIG. 29, in operation 2955, a stack of dielectric layers are deposited on the conductive capping layers. For example, as described with reference to FIG. 30, a stack of dielectric layers 3050 is formed. In some embodiments, the formation of stack of dielectric layers 3050 can include sequential operations of (i) depositing ESL 335A, as shown in FIG. 30, (ii) depositing IMD layer 335B on ESL 335A, as shown in FIG. 30, and (iii) depositing a hard mask layer 3052 (e.g., SiN layer) on IMD layer 335B, as shown in FIG. 30.

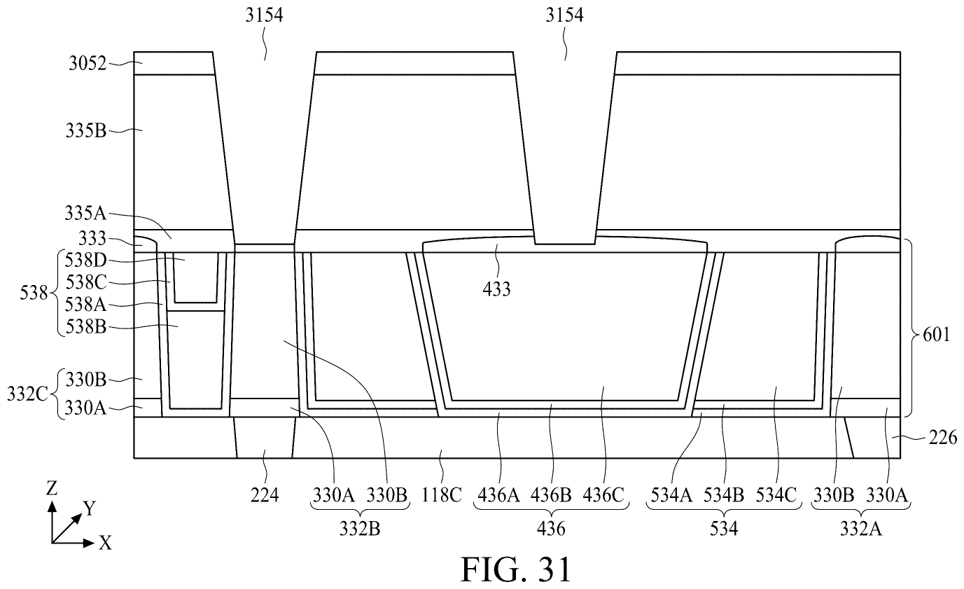

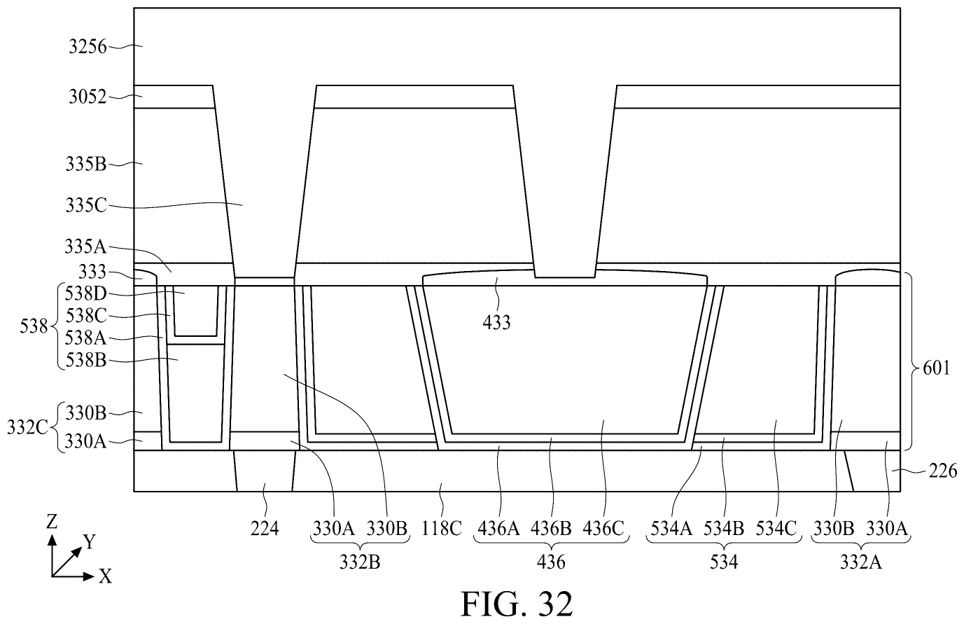

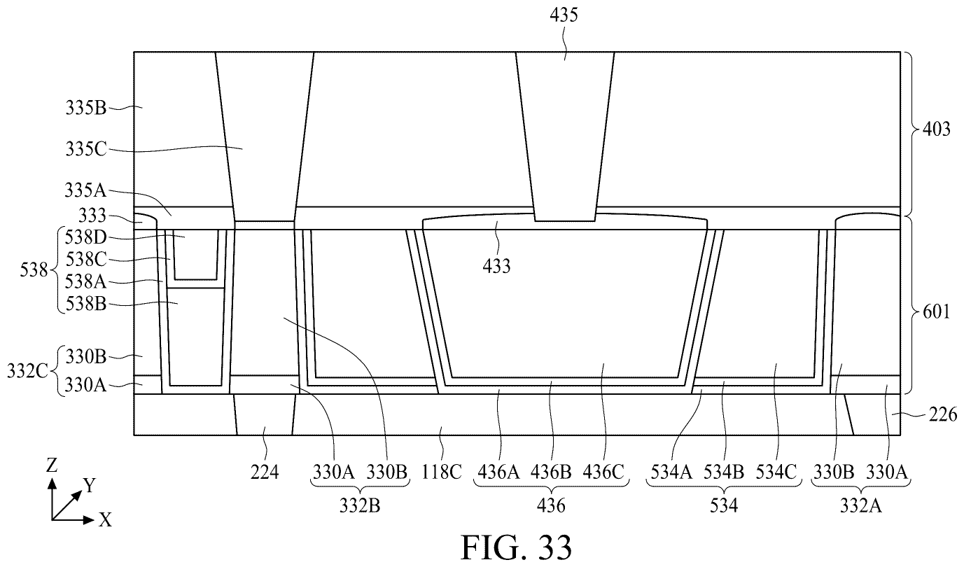

Referring to FIG. 29, in operation 2960, vias are formed on the conductive capping layers. For example, as described with reference to FIGS. 31-33, vias 335C and 435 are formed on conductive capping layers 333 and 433, respectively. The formation of vias 335C and 435 can include sequential operations of (i) forming via openings 3154 on conductive capping layers 333 and 433, as shown in FIG. 31, (ii) depositing a metal layer 3256 to fill via openings 3154, as shown in FIG. 32, and (iii) performing a CMP process on metal layer 3256 to substantially coplanarize top surfaces of IMD layer 335B and vias 335C and 435 and form interconnect structure 403, as shown in FIG. 33. In some embodiments, the formation of via openings 3154 can include etching hard mask layer 3052, IMD layer 335B, and ESL 335A to expose top surfaces of conductive capping layers 333 and 433 on interconnect lines 332B and 436.

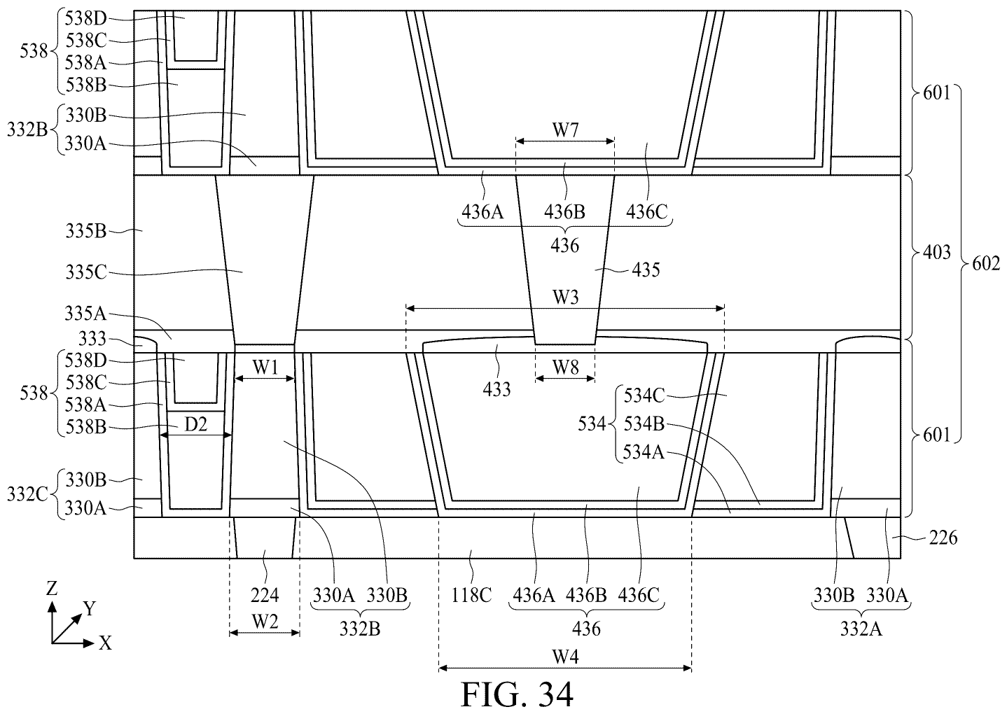

The formation of vias 335C and 435 can be followed by operations 2910-2945 being performed on the structure of FIG. 33, instead of on the transistor, to form interconnect structure 601 on interconnect structure 403, as shown in FIG. 34. In some embodiments, the formation of vias 335C and 435 can be followed by operations 1810-1835 being performed on the structure of FIG. 33, instead of on the transistor, to form interconnect structure 501 on interconnect structure 403 (not shown). In some embodiments, the formation of vias 335C and 435 can be followed by operations 1310-1340 being performed on the structure of FIG. 33, instead of on the transistor, to form interconnect structure 401 on interconnect structure 403, as shown in FIG. 6D. In some embodiments, the formation of vias 335C and 435 can be followed by operations 710-730 performed on the structure of FIG. 33, instead of on the transistor, to form interconnect structure 301 on interconnect structure 403 (not shown).

The present disclosure provides example interconnect structures (e.g., interconnect structures 301, 401, 501, and 601) with reduced resistance and capacitance and example methods (e.g., methods 700, 1300, 1800, and 2400) of forming the example interconnect structures. In some embodiments, an interconnect structure can include interconnect lines (e.g., interconnect lines 332A-332C and 436) with different cross-sectional areas having different metals (e.g., Ru and Cu) to reduce the overall resistance of the interconnect structure. The different metals can have electron mean free path and bulk resistivity different from each other. As electron scattering in metals depends on the electron mean free path length and increase with reduced dimension of metals, thus increasing resistance in metals, the interconnect lines with cross-sectional areas less than about 400 nm² can have metals with electron mean free path lengths shorter than that of metals of the interconnect lines with cross-sectional areas greater than about 400 nm² to reduce resistance in the interconnect structure. Also, the interconnect lines with cross-sectional areas greater than about 400 nm² can have metals with bulk resistivity greater than that of metals of the interconnect lines with cross-sectional areas less than about 400 nm² to reduce resistance in the interconnect structure. In some embodiments, the interconnect structure can include ruthenium (Ru)-based interconnect lines with cross-sectional areas less than about 400 nm² and Cu-based interconnect lines with cross-sectional areas greater than about 400 nm², as Ru has an electron mean free path length shorter than that of Cu and Cu has a bulk resistivity greater than that of Ru.

In some embodiments, interconnect lines with different widths can be formed at different stages of the fabrication process of the interconnect structure to prevent or minimize structural damage to the dielectric fill layers (e.g., dielectric fill layer 1134) of the IMD structures (e.g., IMD structures 334, 534, and 538), thus reducing capacitance of the interconnect structure. In some embodiments, the interconnect lines (e.g., interconnect lines 332A-332C) with widths below 20 nm can be formed prior to the formation of the dielectric fill layers of the IMD structures and the interconnect lines (e.g., interconnect line 436) with widths above 20 nm can be formed after the formation of the dielectric fill layers of the IMD structures. The formation of the interconnect lines with widths below 20 prior to the formation of the dielectric fill layers of the IMD structures can prevent the IMD structures from being exposed to high energy ions used in the formation of interconnect lines in narrow trenches with widths below about 20 nm.

In some embodiments, a structure includes a transistor disposed on a substrate, an IMD structure disposed on the transistor, first and second conductive lines disposed in the IMD structure, and a third conductive line, disposed in the IMD structure. The first conductive line includes a top surface with a first width and a bottom surface with a second width greater than the first width. The third conductive line includes an upper surface with a third width and a lower surface with a fourth width smaller than the third width. Metals of the first and third conductive lines are different from each other.

In some embodiments, a structure includes first, second, and third interconnect lines disposed on the substrate, a first IMD structure disposed between the first and second interconnect lines, a second IMD structure with an air spacer disposed between the second and third interconnect lines, and a fourth interconnect line disposed in the second IMD structure. A metal of the fourth interconnect line has a first bulk resistivity and metals of the first, second, and third interconnect lines have a second bulk resistivity greater than the first bulk resistivity.

In some embodiments, a method includes forming a transistor on a substrate, depositing a stack of conductive layers on the transistor, etching the stack of conductive layers to form first and second conductive structures and an opening between the first and second conductive structures, depositing a dielectric layer on the first and second conductive structures and in the opening, and performing a polishing process on the dielectric layer and the first and second conductive structures. The first conductive structure has a top surface with a first width and a bottom surface with a second width greater than the first width.

The foregoing disclosure outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A structure, comprising:
a transistor disposed on a substrate;
an inter-metal dielectric (IMD) structure disposed on the transistor and comprising:
a dielectric capping layer, and
a dielectric fill layer disposed on the dielectric capping layer; and first and second conductive lines disposed in the IMD structure, wherein:
the first conductive line comprises a top surface with a first width and a bottom surface with a second width greater than the first width; and
the dielectric capping layer is disposed on sidewalls of the first and second conductive lines.

2. The structure of claim 1, wherein the first conductive line comprises a copper-free metal layer.

3. The structure of claim 1, wherein the first conductive line comprises a layer of ruthenium, aluminum, molybdenum, chromium, titanium, or tungsten.

4. The structure of claim 1, wherein the first conductive line comprises:
a metal nitride layer disposed on a contact structure of the transistor; and
a metal layer disposed on the metal nitride layer.

5. The structure of claim 1, further comprising a third conductive line, disposed in the IMD structure, comprising an upper surface with a third width and a lower surface with a fourth width smaller than the third width, wherein metals of the first and third conductive lines are different from each other.

6. The structure of claim 5, wherein the third conductive line comprises a layer of copper.

7. The structure of claim 1, wherein a metal of the first conductive line comprises a first bulk resistivity and a metal of the third conductive line comprises a second bulk resistivity lower than the first bulk resistivity.

8. The structure of claim 1, further comprising a metal of the first conductive line comprises a first electron mean free path length and a metal of the third conductive line comprises a second electron mean free path length shorter than the first electron mean free path length.

9. The structure of claim 1, wherein a width of the first conductive line is smaller than a width of the third conductive line.

10. The structure of claim 1, wherein a cross-sectional area of the first conductive line along a first plane is smaller than a cross-sectional area of the third conductive line along the first plane.

11. A structure, comprising:
a substrate;
first, second, and third interconnect lines disposed on the substrate;
a first inter-metal dielectric (IMD) structure disposed between the first and second interconnect lines;
a second IMD structure comprising an air spacer disposed between the second and third interconnect lines; and
a fourth interconnect line disposed in the second IMD structure, wherein a metal of the fourth interconnect line comprises a first bulk resistivity and metals of the first, second, and third interconnect lines comprise a second bulk resistivity greater than the first bulk resistivity.

12. The structure of claim 11, wherein the second IMD structure further comprises first and second dielectric layers, and
wherein the air spacer is between the first and second dielectric layers.

13. The structure of claim 11, wherein the second IMD structure further comprises first and second dielectric layers,
wherein a bottom surface of first dielectric layer is disposed on the substrate, and
wherein a bottom surface of the second dielectric layer is suspended over the air spacer.

14. The structure of claim 11, wherein the first, second, and third interconnect lines comprise copper-free metal layers.

15. The structure of claim 11, wherein a dielectric constant of the first IMD structure is higher than a dielectric constant of the second IMD structure.

16. The structure of claim 11, wherein a cross-sectional profile of the first interconnect line tapers along a first direction, and
wherein a cross-sectional profile of the fourth interconnect line tapers along a second direction opposite to the first direction.

17. A method, comprising:
forming a transistor on a substrate;
depositing a stack of conductive layers on the transistor;
etching the stack of conductive layers to form first and second conductive structures and an opening between the first and second conductive structures, wherein the first conductive structure comprises a top surface with a first width and a bottom surface with a second width greater than the first width;
depositing a dielectric layer on the first and second conductive structures and in the opening; and
performing a polishing process on the dielectric layer and the first and second conductive structures.

18. The method of claim 17, wherein depositing the stack of conductive layers comprises depositing a copper-free metal layer.

19. The method of claim 17, wherein etching the stack of conductive layers comprises performing a plasma-based etch process on the stack of conductive layers.

20. The method of claim 17, further comprising forming a third conductive structure with a top surface having a third width and a bottom surface having a fourth width smaller than the third width.
